(19) United States
(12) Patent Application Publication
(10) Pub. No.: US 2020/0251522 A1
(43) Pub. Date: Aug. 6, 2020

(54) SUBSTRATE-GATED GROUP III-V TRANSISTORS AND ASSOCIATED FABRICATION METHODS

(71) Applicant: Intel Corporation, Santa Clara, CA (US)

(72) Inventors: Han Wui Then, Portland, OR (US); Marko Radosavljevic, Portland, OR (US); Sansaptak Dasgupta, Hillsboro, OR (US)

(73) Assignee: Intel Corporation, Santa Clara, CA (US)

(21) Appl. No.: 16/649,510

(22) PCT Filed: Dec. 18, 2017
(86) PCT No.: PCT/US2017/067005

§ 371 Date: Mar. 20, 2020

(51) Int. Cl. H01L 27/15; H01L 29/20; H01L 29/778; H01L 33/06; H01L 33/36; H01L 29/417; H01L 29/205; H01L 33/32; H01L 29/66; H01L 29/08; H01L 33/00

(52) U.S. Cl. CPC H01L 27/15; H01L 29/2003; H01L 29/7786; H01L 33/06; H01L 33/36; H01L 29/41725; H01L 21/0254; H01L 33/32; H01L 29/66462; H01L 29/0843; H01L 33/0075; H01L 2933/0016; H01L 29/205

(57) ABSTRACT

Substrate-gated group III-V transistors and associated fabrication methods are described. An example transistor includes a substrate, a gate, and a layer. The gate is located on the substrate. The layer includes a group III material and a group V material. The layer is located on the substrate and the gate. The gate is positioned between the substrate and the layer.

### FIELD OF THE DISCLOSURE

This disclosure relates generally to group III-V transistors and, more specifically, to substrate-gated group III-V transistors and associated fabrication methods.

### BACKGROUND

Known group III-V transistors (e.g., gallium nitride (GaN) transistors) are conventionally gated from only the topside and/or top surface of the device. The topside location of the gate prevents the fabrication of additional structures on the topside of the device.

### BRIEF DESCRIPTION OF THE DRAWINGS

FIG. 1 is a cross-sectional view illustrating a known topside-gated group III-V transistor.

FIG. 2 is a cross-sectional view illustrating a first example substrate-gated group III-V transistor constructed in accordance with the teachings of this disclosure.

FIGS. 3A-3E illustrate an example fabrication process for the first example substrate-gated group III-V transistor of FIG. 2.

FIGS. 4A and 4B are a flowchart representative of an example method for fabricating the first example substrate-gated group III-V transistor of FIGS. 2 and 3A-3E.

FIG. 5 is a cross-sectional view illustrating a second example substrate-gated group III-V transistor constructed in accordance with the teachings of this disclosure.

FIGS. 6A-6F illustrate an example fabrication process for the second example substrate-gated group III-V transistor of FIG. 5.

FIGS. 7A and 7B are a flowchart representative of an example method for fabricating the second example substrate-gated group III-V transistor of FIGS. 5 and 6A-6F.

FIG. 8 is a top view of an example wafer and example dies that may include one or more example substrate-gated group III-V transistors constructed in accordance with the teachings of this disclosure.

FIG. 9 is a cross-sectional side view of an example IC device that may include one or more example substrate-gated group III-V transistors constructed in accordance with the teachings of this disclosure.

FIG. 10 is a cross-sectional side view of an example IC package that may include one or more example substrate-gated group III-V transistors constructed in accordance with the teachings of this disclosure.

FIG. 11 is a cross-sectional side view of an example IC device assembly that may include one or more example substrate-gated group III-V transistors constructed in accordance with the teachings of this disclosure.

FIG. 12 is a block diagram of an example electrical device that may include one or more example substrate-gated group III-V transistors constructed in accordance with the teachings of this disclosure.

Certain examples are shown in the above-identified figures and described in detail below. In describing these examples, like or identical reference numbers are used to identify the same or similar elements. The figures are not necessarily to scale and certain features and certain views of the figures may be shown exaggerated in scale or in schematic for clarity and/or conciseness.

### DETAILED DESCRIPTION

As used herein, the term “group III-V” refers to a chemical composition and/or compound including at least one group III (e.g., IUPAC group 13) element and/or material (e.g., aluminum (Al), gallium (Ga), indium (In), etc.) and at least one group V (e.g., IUPAC group 15) element and/or material (e.g., nitrogen (N), phosphorus (P), arsenic (As), etc.) in any combined relationship and/or ratio. As used herein, the term “layer” refers to a material having an associated thickness, the material to be in contact with, located against, and/or located on a structure (e.g., a substrate, another layer, etc.) as a result of being deposited, grown, and/or otherwise formed against, on, and/or over the structure.

Known group III-V transistors are conventionally gated from only the topside and/or top surface of the device (e.g., the surface of the device located opposite of a substrate of the device). The topside location of the gate prevents the fabrication of additional structures on the topside of the device, and accordingly, in one particular example, prevents such known group III-V transistors from being implemented as backplane transistors for micro light-emitting diode (μLED) applications (e.g., group III-V μLEDs).

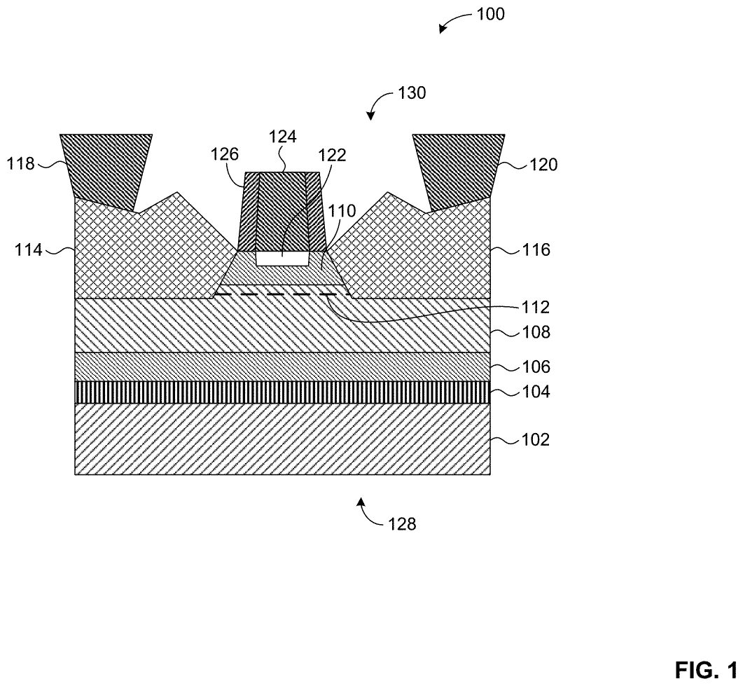

FIG. 1 is a cross-sectional view illustrating a known topside-gated group III-V transistor 100. The topside-gated group III-V transistor 100 of FIG. 1 includes a substrate 102, a first buffer layer 104, a second buffer layer 106, a group III-V layer 108, a polarization layer 110, a two-dimensional electron gas (2DEG) 112, an n-type doped source 114, a n-type doped drain 116, a source contact 118, a drain contact 120, a gate dielectric 122, a gate 124, and an insulating dielectric 126.

The substrate 102 of FIG. 1 is a structural base for fabrication of the topside-gated group III-V transistor 100 of FIG. 1. The substrate 102 is formed from and/or made of silicon (Si) having a (111) planar geometry. The first buffer layer 104 of FIG. 1 contacts, and/or is located against and/or on the substrate 102. The first buffer layer 104 is formed from and/or made of aluminum nitride (AlN). The second buffer layer 106 of FIG. 1 contacts, and/or is located against and/or on the first buffer layer 104. The second buffer layer 106 is formed from and/or made of aluminum gallium nitride (AlGaN).

The group III-V layer 108 of FIG. 1 contacts, and/or is located against and/or on the second buffer layer 106. The group III-V layer 108 is formed from and/or made of gallium nitride (GaN). The polarization layer 110 of FIG. 1 contacts, and/or is located against and/or on the group III-V layer 108. The polarization layer 110 is formed from and/or made of aluminum indium gallium nitride (AlInGaN). The polarization layer 110 is to generate the 2DEG 112 of FIG. 1 within the group III-V layer 108.

The n-type doped source 114 of FIG. 1 and the n-type doped drain 116 of FIG. 1 respectively extend through the polarization layer 110 and partially into the group III-V layer 108 such that the n-type doped source 114 and the n-type doped drain 116 contact the 2DEG 112. When the gate 124 of FIG. 1 is powered and/or turned on (e.g., when a voltage is applied to the gate 124), electrons flowing within the 2DEG 112 of FIG. 1 flow from the n-type doped source 114 toward the n-type doped drain 116. The n-type doped source 212 and the n-type doped drain 214 are respectively formed from and/or made of n-type doped indium gallium nitride (n-InGaN). The source contact 118 of FIG. 1 contacts the n-type doped source 114. The drain contact 120 of FIG. 1 contacts the n-type doped drain 116. The source contact 118 and the drain contact 120 are respectively formed and/or made as a two-layer structure including a tungsten (W) filler and a titanium nitride (TiN) coating.

The gate dielectric 122 of FIG. 1 contacts, and/or is located against and/or on the polarization layer 110. The gate dielectric 122 is formed from and/or made of hafnium oxide (HfO₂). The gate dielectric may additionally or alternatively be formed from and/or made of tantalum pentoxide (Ta₂O₅), zirconium dioxide (ZrO₂), aluminum oxide (Al₂O₃), and/or aluminum nitride (AlN). The gate 124 of FIG. 1 contacts, and/or is located against and/or on the gate dielectric 122. The gate 124 is formed and/or made as a two-layer structure including a tungsten (W) filler and a titanium nitride (TiN) coating. The gate 124 is to receive a voltage to enable an electric field to be generated within the topside-gated group III-V transistor 100 of FIG. 1. The insulating dielectric 126 of FIG. 1 contacts, and/or is located against and/or on the polarization layer 110 and the gate 124. The insulating dielectric 126 is formed from and/or made of silicon dioxide (SiO₂) or silicon mononitride (SiN).

As shown in FIG. 1, the substrate 102 is located at a bottom side 128 of the topside-gated group III-V transistor 100, and the gate 124 is located at a topside 130 of the group III-V transistor 100. The gate 124 is accordingly spaced apart from the substrate 102 of the topside-gated group III-V transistor 100. The topside location of the gate 124 prevents the fabrication of additional structures on the topside 130 of the device, and accordingly prevents the topside-gated group III-V transistor 100 of FIG. 1 from being implemented as backplane transistors for μLED applications (e.g., group III-V μLEDs).

Unlike the known topside-gated group III-V transistor 100 of FIG. 1 described above, the example substrate-gated group III-V transistors and associated fabrication methods disclosed herein include and/or provide for one or more gate(s) located against and/or on (e.g., formed within a cavity of) a substrate of the substrate-gated group III-V transistor. The substrate-based location of the gate(s) advantageously enables the fabrication of additional structures on the topside of the substrate-gated group III-V transistor, thereby enabling the disclosed substrate-gated group III-V transistors to be implemented, for example, as backplane transistors for μLED applications (e.g., group III-V μLEDs).

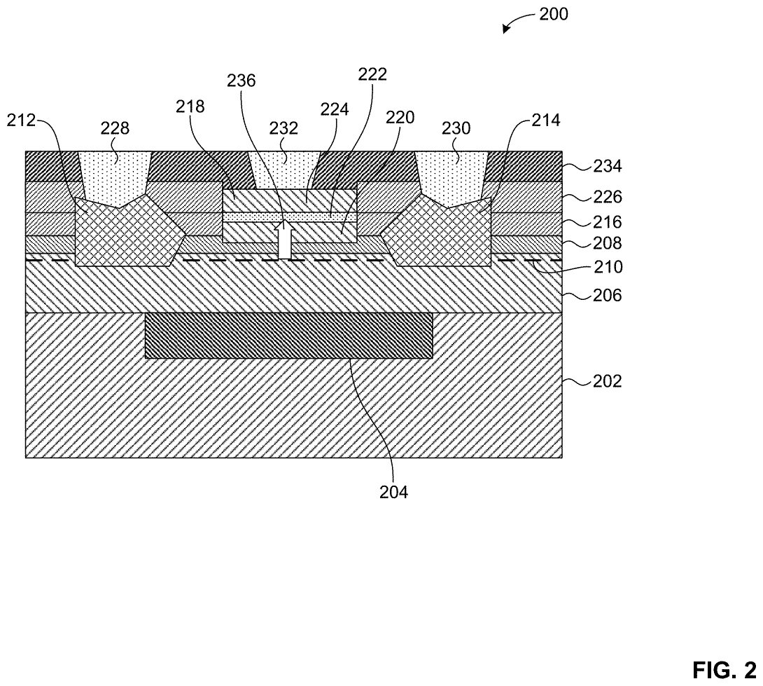

FIG. 2 is a cross-sectional view illustrating a first example substrate-gated group III-V transistor 200 constructed in accordance with the teachings of this disclosure. The example substrate-gated group III-V transistor 200 of FIG. 2 includes an example substrate 202, an example gate 204, an example group III-V layer 206, an example polarization layer 208, an example two-dimensional electron gas (2DEG) 210, an example n-type doped source 212, an example n-type doped drain 214, a first example regrowth layer 216, an example LED structure 218 (e.g., including an example group III-V base 220, an example quantum well 222 and an example p-type doped group III-V cap 224), a second example regrowth layer 226, an example source contact 228, an example drain contact 230, an example LED anode contact 232, and an example interlayer dielectric (ILD) layer 234.

The example substrate 202 of FIG. 2 is a structural base for fabrication of the substrate-gated group III-V transistor 200 of FIG. 2. In the illustrated example of FIG. 2, the substrate 202 is formed from and/or made of silicon (Si). For example, the substrate 202 of FIG. 2 may be formed from and/or made of silicon having a (111) planar geometry. In other examples, the substrate 202 of FIG. 2 may be formed from and/or made of silicon having a planar geometry that differs from the (111) planar geometry. In still other examples, the substrate 202 of FIG. 2 may be formed from and/or made of a material other than silicon.

The example gate 204 of FIG. 2 is to receive a voltage to enable an electric field to be generated within the substrate-gated group III-V transistor 200 of FIG. 2. The gate 204 of FIG. 2 contacts, and/or is located against and/or on (e.g., formed within a cavity of) the substrate 202 of FIG. 2. In some examples, the gate 204 of FIG. 2 may contact, and/or may be located against and/or on the substrate 202 of FIG. 2 as a result of the gate 204 being deposited, grown, and/or otherwise formed against, on, and/or over the substrate 202. In the illustrated example of FIG. 2, the gate 204 is formed from and/or made of titanium (Ti), nitrogen (N), and tungsten (W). For example, the gate 204 of FIG. 2 may be formed and/or made as a two-layer structure including a tungsten filler and a titanium nitride (TiN) coating. In other examples, the gate 204 of FIG. 2 may be formed and/or made as a single-layer structure, and/or may be formed from and/or made of elements and/or materials other than titanium, nitrogen, and/or tungsten.

The example group III-V layer 206 of FIG. 2 contacts, and/or is located against and/or on the substrate 202 and the gate 204 of FIG. 2 such that the gate 204 is located between the substrate 202 and the group III-V layer 206. In some examples, the group III-V layer 206 of FIG. 2 may contact, and/or may be located against and/or on the substrate 202 and the gate 204 of FIG. 2 as a result of the group III-V layer 206 being deposited, grown, and/or otherwise formed against, on, and/or over the substrate 202 and the gate 204. In the illustrated example of FIG. 2, the group III-V layer 206 is formed from and/or made of gallium (Ga) and nitrogen (N). For example, the group III-V layer 206 of FIG. 2 may be formed from and/or made of gallium nitride (GaN). In other examples, the group III-V layer 206 of FIG. 2 may be formed from and/or made of a group III-V compound including elements and/or materials other than gallium and/or nitrogen.

The example polarization layer 208 of FIG. 2 is to generate the example 2DEG 210 of FIG. 2 within the group III-V layer 206. The polarization layer 208 of FIG. 2 contacts, and/or is located against and/or on the group III-V layer 206 of FIG. 2. In some examples, the polarization layer 208 of FIG. 2 may contact, and/or may be located against and/or on the group III-V layer 206 of FIG. 2 as a result of the polarization layer 208 being deposited, grown, and/or otherwise formed against, on, and/or over the group III-V layer 206. In the illustrated example of FIG. 2, the polarization layer 208 is formed from and/or made of aluminum (Al), indium (IN), gallium (Ga), and nitrogen (N). For example, the polarization layer 208 of FIG. 2 may be formed from and/or made of aluminum indium gallium nitride (AlInGaN) having the composition Al₍ₓ₎In_{(y)}Ga_{(1-x-y)}N, where the combined value of (x) and (y) is less than one (e.g., x+y<1). In other examples, the polarization layer 208 of FIG. 2 may be formed from and/or made of aluminum indium gallium nitride having a composition that differs from that described above. In still other examples, the polarization layer 208 of FIG. 2 may be formed from and/or made of a material other than aluminum indium gallium nitride, and/or may be formed from and/or made of elements and/or materials other than aluminum, indium, gallium, and/or nitrogen.

The example n-type doped source 212 of FIG. 2 and the example n-type doped drain 214 of FIG. 2 respectively extend through the polarization layer 208 of FIG. 2 and partially into the group III-V layer 206 of FIG. 2 such that the n-type doped source 212 and the n-type doped drain 214 contact the 2DEG 210 of FIG. 2. Electrons flowing within the 2DEG 210 of FIG. 2 flow from the n-type doped source 212 of FIG. 2 toward the n-type doped drain 214 of FIG. 2. When the gate 204 of FIG. 2 is powered and/or turned on (e.g., when a voltage is applied to the gate 204), electrons flowing within the 2DEG 210 of FIG. 2 are injected into the example quantum well 222 and/or, more generally, into the example LED structure 218 of FIG. 2 in the example direction 236 shown in FIG. 2, thereby causing the LED structure 218 of FIG. 2 to produce light via the LED anode contact 232 of FIG. 2.

In the illustrated example of FIG. 2, the n-type doped source 212 and the n-type doped drain 214 are respectively formed from and/or made of an n-type doped composition of indium (In), gallium (Ga), and nitrogen (N). For example, the n-type doped source 212 and the n-type doped drain 214 may respectively be formed from and/or made of n-type doped indium gallium nitride (n-InGaN) having a ratio of indium to gallium that is between approximately zero and twenty percent (0-20%) indium. In other examples, the n-type doped source 212 and/or the n-type doped drain 214 of FIG. 2 may respectively be formed from and/or made of n-type doped indium gallium nitride having a ratio of indium to gallium that differs from that described above. In still other examples, the n-type doped source 212 and/or the n-type doped drain 214 of FIG. 2 may respectively be formed from and/or made of an n-type doped material other than n-type doped indium gallium nitride, and/or may be formed from and/or made of elements and/or materials other than indium, gallium, and/or nitrogen.

The first example regrowth layer 216 of FIG. 2 contacts, and/or is located against and/or on the polarization layer 208, the n-type doped source 212, and the n-type doped drain 214 of FIG. 2. In some examples, the first regrowth layer 216 of FIG. 2 may contact, and/or may be located against and/or on the polarization layer 208, the n-type doped source 212, and the n-type doped drain 214 of FIG. 2 as a result of the first regrowth layer 216 being deposited, grown, and/or otherwise formed against, on, and/or over the polarization layer 208, the n-type doped source 212, and the n-type doped drain 214.

In the illustrated example of FIG. 2, the first regrowth layer 216 is formed from and/or made of silicon (Si) and nitrogen (N). For example, the first regrowth layer 216 of FIG. 2 may be formed from and/or made of silicon mononitride (SiN). In other examples, the first regrowth layer 216 of FIG. 2 may alternatively be formed from and/or made of (Si) and oxygen (O). For example, the first regrowth layer 216 of FIG. 2 may be formed from and/or made of silicon dioxide (SiO₂). In other examples, the first regrowth layer 216 of FIG. 2 may alternatively be formed from and/or made of aluminum (Al) and oxygen (O). For example, the first regrowth layer 216 of FIG. 2 may be formed from and/or made of aluminum oxide (Al₂O₃). In other examples, the first regrowth layer 216 of FIG. 2 may be formed from a material other than silicon mononitride, silicon dioxide, or aluminum oxide, and/or may be formed from and/or made of elements and/or materials other than silicon, nitrogen, oxygen, and/or aluminum.

The example LED structure 218 of FIG. 2 extends through the first regrowth layer 216 of FIG. 2 and partially into the polarization layer 208 of FIG. 2. The LED structure 218 of FIG. 2 is positioned between the n-type doped source 212 and the n-type doped drain 214 of FIG. 2 to receive electrons from the 2DEG 210 of FIG. 2 when the gate 204 of FIG. 2 is powered and/or turned on (e.g., when a voltage is applied to the gate 204). The LED structure 218 of FIG. 2 includes the example group III-V base 220, the example quantum well 222 and the example p-type doped group III-V cap 224 of FIG. 2, as further described below.

The example group III-V base 220 of FIG. 2 contacts, and/or is located against and/or on the polarization layer 208 of FIG. 2. In some examples, the group III-V base 220 of FIG. 2 may contact, and/or may be located against and/or on the polarization layer 208 of FIG. 2 as a result of the group III-V base 220 being deposited, grown, and/or otherwise formed against, on, and/or over the polarization layer 208. In the illustrated example of FIG. 2, the group III-V base 220 is formed from and/or made of gallium and nitrogen. For example, the group III-V base 220 of FIG. 2 may be formed from and/or made of gallium nitride (GaN). In other examples, the group III-V base 220 of FIG. 2 may be formed from and/or made of a group III-V compound including elements and/or materials other than gallium and/or nitrogen.

The example quantum well 222 of FIG. 2 contacts, and/or is located against and/or on the group III-V base 220 of FIG. 2. In some examples, the quantum well 222 of FIG. 2 may contact, and/or may be located against and/or on the group III-V base 220 of FIG. 2 as a result of the quantum well 222 being deposited, grown, and/or otherwise formed against, on, and/or over the group III-V base 220. In the illustrated example of FIG. 2, the quantum well 222 is formed from and/or made of indium (In), gallium (Ga), and nitrogen (N). For example, the quantum well 222 of FIG. 2 may be formed from and/or made of indium gallium nitride (InGaN) having a ratio of indium to gallium that is selected based on a desired color of light to be extracted from and/or generated by the LED structure 218 of FIG. 2. In some examples, the quantum well 222 may have a ratio of indium to gallium that is approximately thirty percent (30%) indium for blue light, greater than thirty percent (30%) indium for green light, and approximately one hundred percent (100%) indium for red light. In other examples, the quantum well 222 of FIG. 2 may be formed from and/or made of a material other than indium gallium nitride, and/or may be formed from and/or made of elements and/or materials other than indium, gallium, and/or nitrogen.

The example p-type doped group III-V cap 224 of FIG. 2 contacts, and/or is located against and/or on the quantum well 222 of FIG. 2. In some examples, the p-type doped group III-V cap 224 of FIG. 2 may contact, and/or may be located against and/or on the quantum well 222 of FIG. 2 as a result of the p-type doped group III-V cap 224 being deposited, grown, and/or otherwise formed against, on, and/or over the quantum well 222. In the illustrated example of FIG. 2, the p-type doped group III-V cap 224 is formed from and/or made of a p-type doped composition of gallium (Ga) and nitrogen (N). For example, the p-type group III-V cap 224 of FIG. 2 may be formed from and/or made of p-type doped gallium nitride (P-GaN). In other examples, the p-type doped group III-V cap 224 of FIG. 2 may be formed from and/or made of a p-type doped group III-V compound including elements and/or materials other than gallium and/or nitrogen.

The second example regrowth layer 226 of FIG. 2 contacts, and/or is located against and/or on the n-type doped source 212, the n-type doped drain 214, the first regrowth layer 216, and the LED structure 218 (e.g., the quantum well 222 and/or the p-type doped group III-V cap 224 of the LED structure 218) of FIG. 2. In some examples, the second regrowth layer 226 of FIG. 2 may contact, and/or may be located against and/or on the n-type doped source 212, the n-type doped drain 214, the first regrowth layer 216, and the LED structure 218 of FIG. 2 as a result of the second regrowth layer 226 being deposited, grown, and/or otherwise formed against, on, and/or over the n-type doped source 212, the n-type doped drain 214, the first regrowth layer 216, and the LED structure 218.

In the illustrated example of FIG. 2, the second regrowth layer 226 is formed from and/or made of silicon (Si) and nitrogen (N). For example, the second regrowth layer 226 of FIG. 2 may be formed from and/or made of silicon mononitride (SiN). In other examples, the second regrowth layer 226 of FIG. 2 may alternatively be formed from and/or made of (Si) and oxygen (O). For example, the second regrowth layer 226 of FIG. 2 may be formed from and/or made of silicon dioxide (SiO₂). In other examples, the second regrowth layer 226 of FIG. 2 may alternatively be formed from and/or made of aluminum (Al) and oxygen (O). For example, the second regrowth layer 226 of FIG. 2 may be formed from and/or made of aluminum oxide (Al₂O₃). In other examples, the second regrowth layer 226 of FIG. 2 may be formed from a material other than silicon mononitride, silicon dioxide, or aluminum oxide, and/or may be formed from and/or made of elements and/or materials other than silicon, nitrogen, oxygen, and/or aluminum.

The example source contact 228 of FIG. 2 extends through the second regrowth layer 226 of FIG. 2 and contacts the n-type doped source 212 of FIG. 2. The example drain contact 230 of FIG. 2 extends through the second regrowth layer 226 of FIG. 2 and contacts the n-type doped drain 214 of FIG. 2. The example LED anode contact 232 of FIG. 2 contacts the p-type doped group III-V cap 224 of the LED structure 218 of FIG. 2. In the illustrated example of FIG. 2, the source contact 228, the drain contact 230, and the LED anode contact 232 are respectively formed from and/or made of one or more transparent and/or translucent metal material(s). Fabrication of the source contact 228, the drain contact 230, and the LED anode contact 232 from transparent and/or translucent metal materials advantageously allows for light extraction from the topside of the substrate-gated group III-V transistor 200 of FIG. 2. In some examples, the source contact 228, the drain contact 230, and/or the LED anode contact 232 of FIG. 2 may respectively be formed from and/or made of indium tin oxide (ITO). In other examples, the source contact 228, the drain contact 230, and/or the LED anode contact 232 of FIG. 2 may respectively be formed from and/or made of a transparent and/or translucent metal material other than indium tin oxide (ITO). In still other examples, the source contact 228, the drain contact 230, and/or the LED anode contact 232 of FIG. 2 may respectively be formed from and/or made of a material other than a transparent and/or translucent metal material.

The example ILD layer 234 of FIG. 2 contacts, and/or is located against and/or on the LED structure 218 (e.g., the p-type doped group III-V cap 224 of the LED structure 218), the second regrowth layer 226, the source contact 228, the drain contact 230, and the LED anode contact 232 of FIG. 2. In some examples, the ILD layer 234 of FIG. 2 may contact, and/or may be located against and/or on the LED structure 218, the second regrowth layer 226, the source contact 228, the drain contact 230, and the LED anode contact 232 of FIG. 2 as a result of the ILD layer 234 being deposited, grown, and/or otherwise formed against, on, and/or over the LED structure 218, the second regrowth layer 226, the source contact 228, the drain contact 230, and the LED anode contact 232. In the illustrated example of FIG. 2, the ILD layer 234 is formed from and/or made of silicon (Si) and oxygen (O). For example, the ILD layer 234 of FIG. 2 may be formed from and/or made of silicon dioxide (SiO₂). In other examples, the ILD layer 234 of FIG. 2 may be formed from and/or made of a material other than silicon dioxide, and/or may be formed from and/or made of elements and/or materials other than silicon and oxygen.

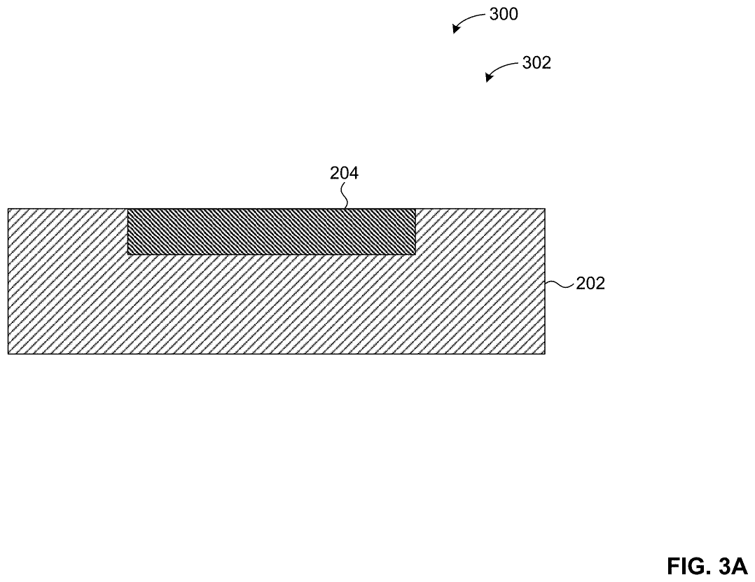

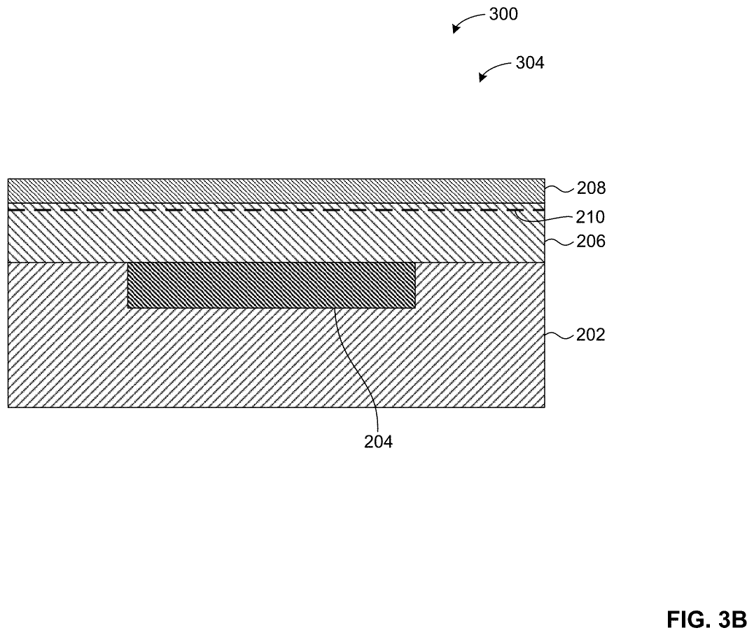

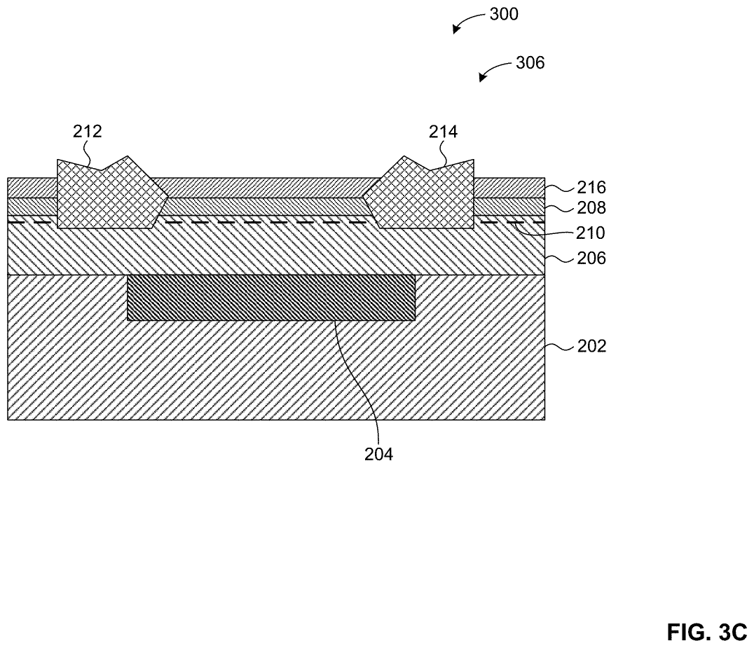

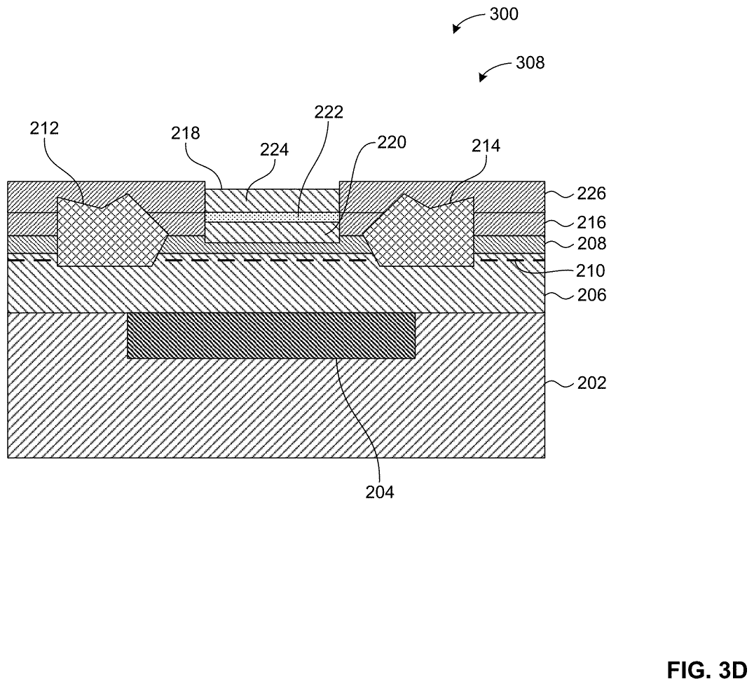

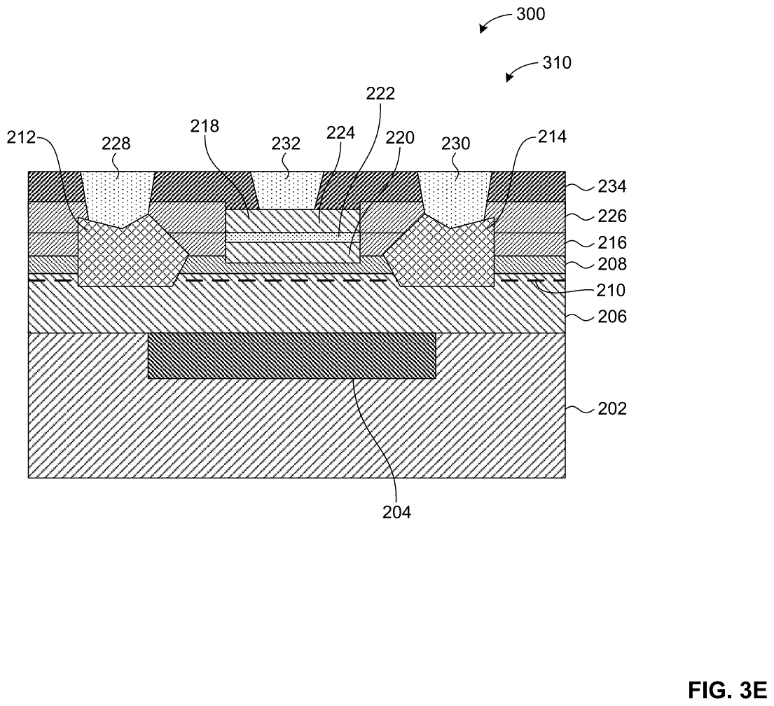

FIGS. 3A-3E illustrate an example fabrication process 300 for the first example substrate-gated group III-V transistor 200 of FIG. 2. FIG. 3A illustrates a first example phase 302 of the fabrication process 300. As shown in the illustrated example of FIG. 3A, the first phase 302 of the fabrication process 300 includes forming and/or locating the gate 204 of FIG. 2 against and/or on the substrate 202 of FIG. 2. For example, the gate 204 of FIG. 2 may contact, and/or may be located against and/or on the substrate 202 of FIG. 2 as a result of the gate 204 being deposited, grown, and/or otherwise formed against, on, and/or over the substrate 202 in connection with the first phase 302 of FIG. 3A.

FIG. 3B illustrates a second example phase 304 of the fabrication process 300 to be performed subsequent to the first phase 302 of the fabrication process 300. As shown in the illustrated example of FIG. 3B, the second phase 304 of the fabrication process 300 includes forming and/or locating the group III-V layer 206 of FIG. 2 against and/or on the substrate 202 and the gate 204 of FIG. 2. For example, the group III-V layer 206 of FIG. 2 may contact, and/or may be located against and/or on the substrate 202 and the gate 204 of FIG. 2 as a result of the group III-V layer 206 being deposited, grown, and/or otherwise formed against, on, and/or over the substrate 202 and the gate 204 in connection with the second phase 304 of FIG. 3B.

As further shown in the illustrated example of FIG. 3B, the second phase 304 of the fabrication process 300 also includes forming and/or locating the polarization layer 208 of FIG. 2 against and/or on the group III-V layer 206 of FIG. 2 to generate the 2DEG 210 of FIG. 2. For example, the polarization layer 208 of FIG. 2 may contact, and/or may be located against and/or on the group III-V layer 206 of FIG. 2 as a result of the polarization layer 208 being deposited, grown, and/or otherwise formed against, on, and/or over the group III-V layer 206 in connection with the second phase 304 of FIG. 3B.

FIG. 3C illustrates a third example phase 306 of the fabrication process 300 to be performed subsequent to the second phase 304 of the fabrication process 300. As shown in the illustrated example of FIG. 3C, the third phase 306 of the fabrication process 300 includes forming and/or locating the n-type doped source 212 and the n-type doped drain 214 of FIG. 2 against and/or on the group III-V layer 206 of FIG. 2 such that the n-type doped source 212 and the n-type doped drain 214 extend through the polarization layer 208 of FIG. 2 and partially into the group III-V layer 206 to contact the 2DEG 210 of FIG. 2. For example, the n-type doped source 212 and the n-type doped drain 214 of FIG. 2 may contact, and/or may be located against and/or on the 2DEG 210 of the group III-V layer 206 of FIG. 2 as a result of the n-type doped source 212 and the n-type doped drain 214 being deposited, grown, and/or otherwise formed against, on, and/or over the group III-V layer 206 in connection with the third phase 306 of FIG. 3C.

As further shown in the illustrated example of FIG. 3C, the third phase 306 of the fabrication process 300 also includes forming and/or locating the first regrowth layer 216 of FIG. 2 against and/or on the polarization layer 208, the n-type doped source 212, and n-type doped drain 214 of FIG. 2. For example, the first regrowth layer 216 of FIG. 2 may contact, and/or may be located against and/or on the polarization layer 208, the n-type doped source 212, and n-type doped drain 214 of FIG. 2 as a result of the first regrowth layer 216 being deposited, grown, and/or otherwise formed against, on, and/or over the polarization layer 208, the n-type doped source 212, and n-type doped drain 214 in connection with the third phase 306 of FIG. 3C.

FIG. 3D illustrates a fourth example phase 308 of the fabrication process 300 to be performed subsequent to the third phase 306 of the fabrication process 300. As shown in the illustrated example of FIG. 3D, the fourth phase 308 of the fabrication process 300 includes forming and/or locating the LED structure 218 of FIG. 2 against and/or on the polarization layer 208 of FIG. 2 such that the LED structure 218 extends through the first regrowth layer 216 of FIG. 2 and partially into the polarization layer 208. For example, the LED structure 218 of FIG. 2 may contact, and/or may be located against and/or on the polarization layer 208 of FIG. 2 as a result of the LED structure 218 being deposited, grown, and/or otherwise formed against, on, and/or over the polarization layer 208 in connection with the fourth phase 308 of FIG. 3D. In some examples, the group III-V base 220 of the LED structure 218 of FIG. 2 may be deposited, grown, and/or otherwise formed against, on, and/or over the polarization layer 208, the quantum well 222 of the LED structure 218 of FIG. 2 may be deposited, grown, and/or otherwise formed against, on, and/or over the group III-V base 220, and the p-type doped group III-V cap 224 of the LED structure 218 of FIG. 2 may be deposited, grown, and/or otherwise formed against, on, and/or over the quantum well 222 in connection with the fourth phase 308 of FIG. 3D.

As further shown in the illustrated example of FIG. 3D, the fourth phase 308 of the fabrication process 300 also includes forming and/or locating the second regrowth layer 226 of FIG. 2 against and/or on the n-type doped source 212, the n-type doped drain 214, the first regrowth layer 216, and the LED structure 218 (e.g., the quantum well 222 and/or the p-type doped group III-V cap 224 of the LED structure 218) of FIG. 2. For example, the second regrowth layer 226 of FIG. 2 may contact, and/or may be located against and/or on the n-type doped source 212, the n-type doped drain 214, the first regrowth layer 216, and the LED structure 218 of FIG. 2 as a result of the second regrowth layer 226 being deposited, grown, and/or otherwise formed against, on, and/or over the n-type doped source 212, the n-type doped drain 214, the first regrowth layer 216, and the LED structure 218 in connection with the fourth phase 308 of FIG. 3D.

FIG. 3E illustrates a fifth example phase 310 of the fabrication process 300 to be performed subsequent to the fourth phase 308 of the fabrication process 300. As shown in the illustrated example of FIG. 3E, the fifth phase 310 of the fabrication process 300 includes forming and/or locating the source contact 228 of FIG. 2 against and/or on the n-type doped source 212 of FIG. 2 such that the source contact 228 extends through the second regrowth layer 226 of FIG. 2 to contact the n-type doped source 212. For example, the source contact 228 of FIG. 2 may contact, and/or may be located against and/or on the n-type doped source 212 of FIG. 2 as a result of the source contact 228 being deposited, grown, and/or otherwise formed against, on, and/or over the n-type doped source 212 in connection with the fifth phase 310 of FIG. 3E.

As further shown in the illustrated example of FIG. 3E, the fifth phase 310 of the fabrication process 300 also includes forming and/or locating the drain contact 230 of FIG. 2 against and/or on the n-type doped drain 214 of FIG. 2 such that the drain contact 230 extends through the second regrowth layer 226 of FIG. 2 to contact the n-type doped drain 214. For example, the drain contact 230 of FIG. 2 may contact, and/or may be located against and/or on the n-type doped drain 214 of FIG. 2 as a result of the drain contact 230 being deposited, grown, and/or otherwise formed against, on, and/or over the n-type doped drain 214 in connection with the fifth phase 310 of FIG. 3E.

As further shown in the illustrated example of FIG. 3E, the fifth phase 310 of the fabrication process 300 also includes forming and/or locating the LED anode contact 232 of FIG. 2 against and/or on the LED structure 218 (e.g., the p-type doped group III-V cap 224 of the LED structure 218) of FIG. 2. For example, the LED anode contact 232 of FIG. 2 may contact, and/or may be located against and/or on the LED structure 218 of FIG. 2 as a result of the LED anode contact 232 being deposited, grown, and/or otherwise formed against, on, and/or over the LED structure 218 in connection with the fifth phase 310 of FIG. 3E.

As further shown in the illustrated example of FIG. 3E, the fifth phase 310 of the fabrication process 300 also includes forming and/or locating the ILD layer 234 of FIG. 2 against and/or on the LED structure 218 (e.g., the p-type doped group III-V cap 224 of the LED structure 218), the second regrowth layer 226, the source contact 228, the drain contact 230, and the LED anode contact 232 of FIG. 2. For example, the ILD layer 234 of FIG. 2 may contact, and/or may be located against and/or on the LED structure 218, the second regrowth layer 226, the source contact 228, the drain contact 230, and the LED anode contact 232 of FIG. 2 as a result of the ILD layer 234 being deposited, grown, and/or otherwise formed against, on, and/or over the LED structure 218, the second regrowth layer 226, the source contact 228, the drain contact 230, and the LED anode contact 232 in connection with the fifth phase 310 of FIG. 3E.

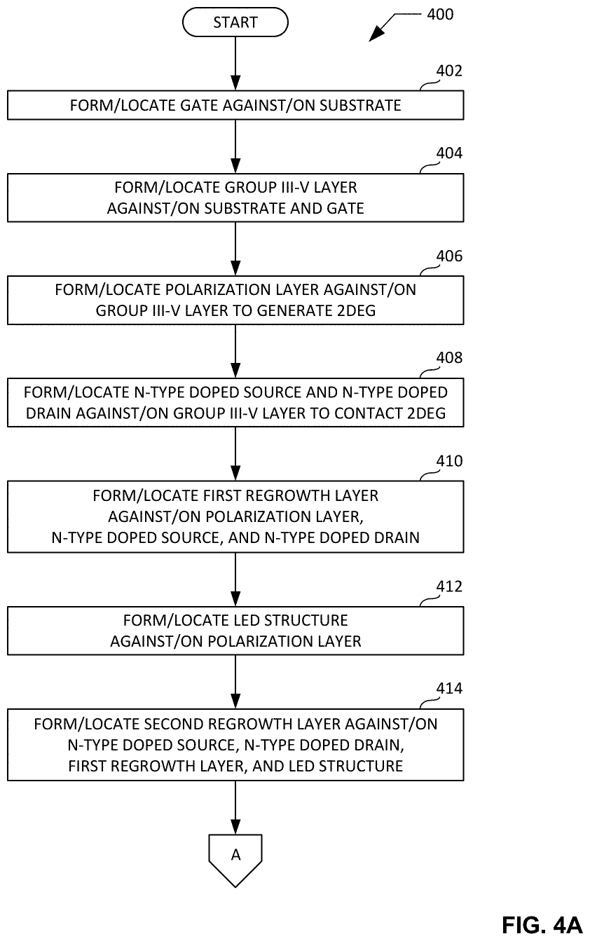

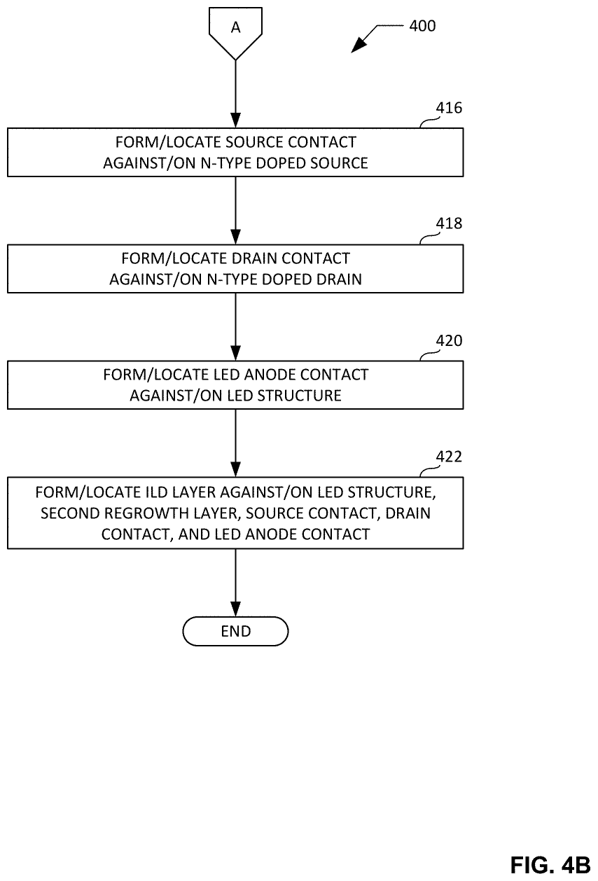

FIGS. 4A and 4B are a flowchart representative of an example method 400 for fabricating the first example substrate-gated group III-V transistor 200 of FIGS. 2 and 3A-3E. The example method 400 of FIGS. 4A and 4B includes forming and/or locating the gate 204 of FIG. 2 against and/or on the substrate 202 of FIG. 2 (block 402). For example, the gate 204 of FIG. 2 may contact, and/or may be located against and/or on the substrate 202 of FIG. 2 as a result of the gate 204 being deposited, grown, and/or otherwise formed against, on, and/or over the substrate 202, as described above in connection with the first phase 302 of FIG. 3A.

The example method 400 of FIGS. 4A and 4B also includes forming and/or locating the group III-V layer 206 of FIG. 2 against and/or on the substrate 202 and the gate 204 of FIG. 2 (block 404). For example, the group III-V layer 206 of FIG. 2 may contact, and/or may be located against and/or on the substrate 202 and the gate 204 of FIG. 2 as a result of the group III-V layer 206 being deposited, grown, and/or otherwise formed against, on, and/or over the substrate 202 and the gate 204, as described above in connection with the second phase 304 of FIG. 3B.

The example method 400 of FIGS. 4A and 4B also includes forming and/or locating the polarization layer 208 of FIG. 2 against and/or on the group III-V layer 206 of FIG. 2 to generate the 2DEG 210 of FIG. 2 (block 406). For example, the polarization layer 208 of FIG. 2 may contact, and/or may be located against and/or on the group III-V layer 206 of FIG. 2 as a result of the polarization layer 208 being deposited, grown, and/or otherwise formed against, on, and/or over the group III-V layer 206, as described above in connection with the second phase 304 of FIG. 3B.

The example method 400 of FIGS. 4A and 4B also includes forming and/or locating the n-type doped source 212 and the n-type doped drain 214 of FIG. 2 against and/or on the group III-V layer 206 of FIG. 2 such that the n-type doped source 212 and the n-type doped drain 214 contact the 2DEG 210 of FIG. 2 (block 408). For example, the n-type doped source 212 and the n-type doped drain 214 of FIG. 2 may contact, and/or may be located against and/or on the 2DEG 210 of the group III-V layer 206 of FIG. 2 as a result of the n-type doped source 212 and the n-type doped drain 214 being deposited, grown, and/or otherwise formed against, on, and/or over the group III-V layer 206, as described above in connection with the third phase 306 of FIG. 3C.

The example method 400 of FIGS. 4A and 4B also includes forming and/or locating the first regrowth layer 216 of FIG. 2 against and/or on the polarization layer 208, the n-type doped source 212, and n-type doped drain 214 of FIG. 2 (block 410). For example, the first regrowth layer 216 of FIG. 2 may contact, and/or may be located against and/or on the polarization layer 208, the n-type doped source 212, and n-type doped drain 214 of FIG. 2 as a result of the first regrowth layer 216 being deposited, grown, and/or otherwise formed against, on, and/or over the polarization layer 208, the n-type doped source 212, and n-type doped drain 214, as described above in connection with the third phase 306 of FIG. 3C.

The example method 400 of FIGS. 4A and 4B also includes forming and/or locating the LED structure 218 of FIG. 2 against and/or on the polarization layer 208 of FIG. 2 such that the LED structure 218 (block 412). For example, the LED structure 218 of FIG. 2 may contact, and/or may be located against and/or on the polarization layer 208 of FIG. 2 as a result of the LED structure 218 being deposited, grown, and/or otherwise formed against, on, and/or over the polarization layer 208, as described above in connection with the fourth phase 308 of FIG. 3D.

The example method 400 of FIGS. 4A and 4B also includes forming and/or locating the second regrowth layer 226 of FIG. 2 against and/or on the n-type doped source 212, the n-type doped drain 214, the first regrowth layer 216, and the LED structure 218 (e.g., the quantum well 222 and/or the p-type doped group cap 224 of the LED structure 218) of FIG. 2 (block 414). For example, the second regrowth layer 226 of FIG. 2 may contact, and/or may be located against and/or on the n-type doped source 212, the n-type doped drain 214, the first regrowth layer 216, and the LED structure 218 of FIG. 2 as a result of the second regrowth layer 226 being deposited, grown, and/or otherwise formed against, on, and/or over the n-type doped source 212, the n-type doped drain 214, the first regrowth layer 216, and the LED structure 218, as described above in connection with the fourth phase 308 of FIG. 3D.

The example method 400 of FIGS. 4A and 4B also includes forming and/or locating the source contact 228 of FIG. 2 against and/or on the n-type doped source 212 of FIG. 2 (block 416). For example, the source contact 228 of FIG. 2 may contact, and/or may be located against and/or on the n-type doped source 212 of FIG. 2 as a result of the source contact 228 being deposited, grown, and/or otherwise formed against, on, and/or over the n-type doped source 212, as described above in connection with the fifth phase 310 of FIG. 3E.

The example method 400 of FIGS. 4A and 4B also includes forming and/or locating the drain contact 230 of FIG. 2 against and/or on the n-type doped drain 214 of FIG. 2 (block 418). For example, the drain contact 230 of FIG. 2 may contact, and/or may be located against and/or on the n-type doped drain 214 of FIG. 2 as a result of the drain contact 230 being deposited, grown, and/or otherwise formed against, on, and/or over the n-type doped drain 214, as described above in connection with the fifth phase 310 of FIG. 3E.

The example method 400 of FIGS. 4A and 4B includes forming and/or locating the LED anode contact 232 of FIG. 2 against and/or on the LED structure 218 (e.g., the p-type doped group III-V cap 224 of the LED structure 218) of FIG. 2 (block 420). For example, the LED anode contact 232 of FIG. 2 may contact, and/or may be located against and/or on the LED structure 218 of FIG. 2 as a result of the LED anode contact 232 being deposited, grown, and/or otherwise formed against, on, and/or over the LED structure 218, as described above in connection with the fifth phase 310 of FIG. 3E.

The example method 400 of FIGS. 4A and 4B also includes forming and/or locating the ILD layer 234 of FIG. 2 against and/or on the LED structure 218 (e.g., the p-type doped group III-V cap 224 of the LED structure 218), the second regrowth layer 226, the source contact 228, the drain contact 230, and the LED anode contact 232 of FIG. 2 (block 422). For example, the ILD layer 234 of FIG. 2 may contact, and/or may be located against and/or on the LED structure 218, the second regrowth layer 226, the source contact 228, the drain contact 230, and the LED anode contact 232 of FIG. 2 as a result of the ILD layer 234 being deposited, grown, and/or otherwise formed against, on, and/or over the LED structure 218, the second regrowth layer 226, the source contact 228, the drain contact 230, and the LED anode contact 232 of FIG. 2, as described above in connection with the fifth phase 310 of FIG. 3E. Following block 422, the example method 400 of FIGS. 4A and 4B ends.

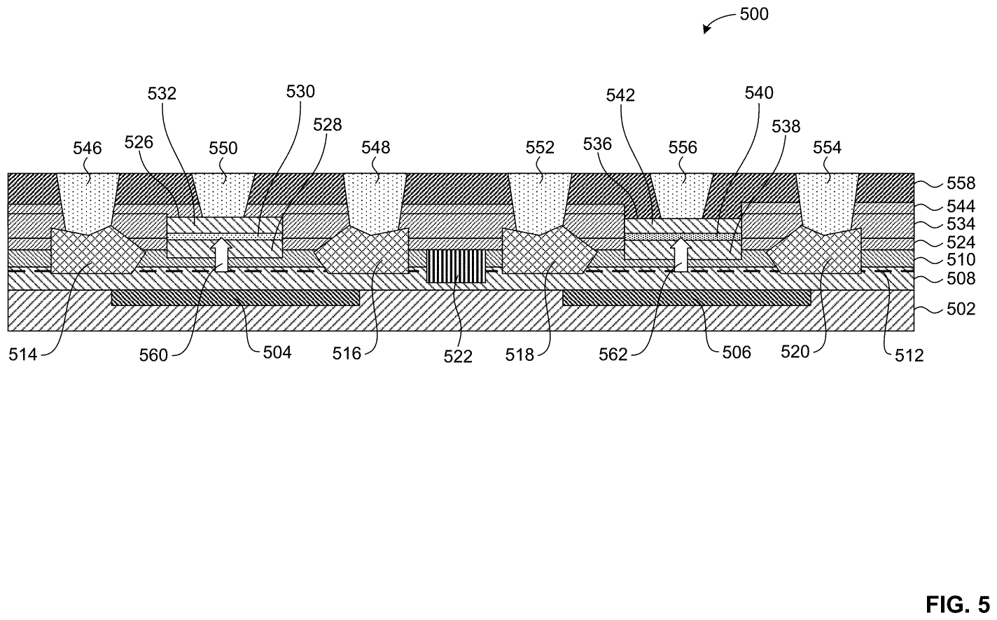

FIG. 5 is a cross-sectional view illustrating a second example substrate-gated group III-V transistor 500 constructed in accordance with the teachings of this disclosure. The example substrate-gated group III-V transistor 500 of FIG. 5 includes an example substrate 502, a first example gate 504, a second example gate 506, an example group III-V layer 508, an example polarization layer 510, an example two-dimensional electron gas (2DEG) 512, a first example n-type doped source 514, a first example n-type doped drain 516, a second example n-type doped source 518, a second example n-type doped drain 520, an example isolation structure 522, a first example regrowth layer 524, a first example LED structure 526 (e.g., including a first example group III-V base 528, a first example quantum well 530 and a first example p-type doped group III-V cap 532), a second example regrowth layer 534, a second example LED structure 536 (e.g., including a second example group III-V base 538, a second example quantum well 540 and a second example p-type doped group III-V cap 542), a third example regrowth layer 544, a first example source contact 546, a first example drain 548, a first example LED anode contact 550, a second example source contact 552, a second example drain 554, a second example LED anode contact 556, and an example interlayer dielectric (ILD) layer 558.

The example substrate 502 of FIG. 5 is a structural base for fabrication of the substrate-gated group III-V transistor 500 of FIG. 5. In the illustrated example of FIG. 5, the substrate 502 is formed from and/or made of silicon (Si). For example, the substrate 502 of FIG. 5 may be formed from and/or made of silicon having a (111) planar geometry. In other examples, the substrate 502 of FIG. 5 may be formed from and/or made of silicon having a planar geometry that differs from the (111) planar geometry. In still other examples, the substrate 502 of FIG. 5 may be formed from and/or made of a material other than silicon.

The first example gate 504 and the second example gate 506 of FIG. 5 are to respectively receive a voltage (e.g., independent voltages, or a common voltage) to enable corresponding respective electric fields to be generated within the substrate-gated group III-V transistor 500 of FIG. 5. The first gate 504 and the second gate 506 of FIG. 5 contact, and/or are located against and/or on (e.g., formed within cavities of) the substrate 502 of FIG. 5. In some examples, the first gate 504 and the second gate 506 of FIG. 5 may contact, and/or may be located against and/or on the substrate 502 of FIG. 5 as a result of the first gate 504 and the second gate 506 being deposited, grown, and/or otherwise formed against, on, and/or over the substrate 502. In the illustrated example of FIG. 5, the first gate 504 and the second gate 506 are respectively formed from and/or made of titanium (Ti), nitrogen (N), and tungsten (W). For example, the first gate 504 and the second gate 506 of FIG. 5 may respectively be formed and/or made as a two-layer structure including a tungsten filler and a titanium nitride (TiN) coating. In other examples, the first gate 504 and/or the second gate 506 of FIG. 5 may respectively be formed and/or made as a single-layer structure, and/or may respectively be formed from and/or made of elements and/or materials other than titanium, nitrogen, and/or tungsten.

The example group III-V layer 508 of FIG. 5 contacts, and/or is located against and/or on the substrate 502, the first gate 504, and the second gate 506 of FIG. 5 such that the first gate 504 and the second gate 506 are located between the substrate 502 and the group III-V layer 508. In some examples, the group III-V layer 508 of FIG. 5 may contact, and/or may be located against and/or on the substrate 502, the first gate 504, and the second gate 506 of FIG. 5 as a result of the group III-V layer 508 being deposited, grown, and/or otherwise formed against, on, and/or over the substrate 502, the first gate 504, and the second gate 506. In the illustrated example of FIG. 5, the group III-V layer 508 is formed from and/or made of gallium (Ga) and nitrogen (N). For example, the group III-V layer 508 of FIG. 5 may be formed from and/or made of gallium nitride (GaN). In other examples, the group III-V layer 508 of FIG. 5 may be formed from and/or made of a group III-V compound including elements and/or materials other than gallium and/or nitrogen.

The example polarization layer 510 of FIG. 5 is to generate the example 2DEG 512 of FIG. 5 within the group III-V layer 508. The polarization layer 510 of FIG. 5 contacts, and/or is located against and/or on the group III-V layer 508 of FIG. 5. In some examples, the polarization layer 510 of FIG. 5 may contact, and/or may be located against and/or on the group III-V layer 508 of FIG. 5 as a result of the polarization layer 510 being deposited, grown, and/or otherwise formed against, on, and/or over the group III-V layer 508. In the illustrated example of FIG. 5, the polarization layer 510 is formed from and/or made of aluminum (Al), indium (IN), gallium (Ga), and nitrogen (N). For example, the polarization layer 510 of FIG. 5 may be formed from and/or made of aluminum indium gallium nitride (AlInGaN) having the composition Al₍ₓ₎In_{(y)}Ga_{(1-x-y)}N, where the combined value of (x) and (y) is less than one (e.g., x+y<1). In other examples, the polarization layer 510 of FIG. 5 may be formed from and/or made of aluminum indium gallium nitride having a composition that differs from that described above. In still other examples, the polarization layer 510 of FIG. 5 may be formed from and/or made of a material other than aluminum indium gallium nitride, and/or may be formed from and/or made of elements and/or materials other than aluminum, indium, gallium, and/or nitrogen.

The first example n-type doped source 514, the first example n-type doped drain 516, the second example n-type doped source 518, and the second example n-type doped drain 520 of FIG. 5 respectively extend through the polarization layer 510 of FIG. 5 and partially into the group III-V layer 508 of FIG. 5 such that the first n-type doped source 514, the first n-type doped drain 516, the second n-type doped source 518, and the second n-type doped drain 520 contact the 2DEG 512 of FIG. 5. Electrons flowing within the 2DEG 512 of FIG. 5 flow from the first n-type doped source 514 of FIG. 5 toward the first n-type doped drain 516 of FIG. 5. Electrons flowing within the 2DEG 512 of FIG. 5 flow from the second n-type doped source 518 of FIG. 5 toward the second n-type doped drain 520 of FIG. 5. The example isolation structure 522 of FIG. 5 prevents electrons flowing within the 2DEG 512 of FIG. 5 from flowing between the second n-type doped source 518 of FIG. 5 and the first n-type doped drain 516 of FIG. 5. When the first gate 504 of FIG. 5 is powered and/or turned on (e.g., when a voltage is applied to the first gate 504), electrons flowing within the 2DEG 512 of FIG. 5 are injected into the first example quantum well 530 and/or, more generally, into the first example LED structure 526 of FIG. 5 in the first example direction 560 shown in FIG. 5, thereby causing the first LED structure 526 of FIG. 5 to produce light via the first LED anode contact 550 of FIG. 5. When the second gate 506 of FIG. 5 is powered and/or turned on (e.g., when a voltage is applied to the second gate 506), electrons flowing within the 2DEG 512 of FIG. 5 are injected into the second example quantum well 540 and/or, more generally, into the second example LED structure 536 of FIG. 5 in the second example direction 562 shown in FIG. 5, thereby causing the second LED structure 536 of FIG. 5 to produce light via the second LED anode contact 556 of FIG. 5.

In the illustrated example of FIG. 5, the first n-type doped source 514, the first n-type doped drain 516, the second n-type doped source 518, and the second n-type doped drain 520 are respectively formed from and/or made of an n-type doped composition of indium (In), gallium (Ga), and nitrogen (N). For example, first n-type doped source 514, the first n-type doped drain 516, the second n-type doped source 518, and the second n-type doped drain 520 may respectively be formed from and/or made of n-type doped indium gallium nitride (n-InGaN) having a ratio of indium to gallium that is between approximately zero and twenty percent (0-20%) indium. In other examples, the first n-type doped source 514, the first n-type doped drain 516, the second n-type doped source 518, and/or the second n-type doped drain 520 of FIG. 5 may respectively be formed from and/or made of n-type doped indium gallium nitride having a ratio of indium to gallium that differs from that described above. In still other examples, the first n-type doped source 514, the first n-type doped drain 516, the second n-type doped source 518, and/or the second n-type doped drain 520 of FIG. 5 may respectively be formed from and/or made of an n-type doped material other than n-type doped indium gallium nitride, and/or may be formed from and/or made of elements and/or materials other than indium, gallium, and/or nitrogen.

The example isolation structure 522 of FIG. 5 is to prevent electrons flowing within the 2DEG 512 of FIG. 5 from flowing between the second n-type doped 518 of FIG. 5 and the first n-type doped drain 516 of FIG. 5. The isolation structure 522 of FIG. 5 extends through the polarization layer 510 of FIG. 5 and partially into the group III-V layer 508 of FIG. 5 such that the isolation structure 522 blocks the 2DEG 512 of FIG. 5. In the illustrated example of FIG. 5, the isolation structure 522 is formed from and/or made of silicon (Si) and oxygen (O). For example, the isolation structure 522 of FIG. 5 may be formed from and/or made of silicon dioxide (SiO₂). In other examples, the isolation structure 522 of FIG. 5 may be formed from and/or made of a material other than silicon dioxide, and/or may be formed from and/or made of elements and/or materials other than silicon and oxygen.

The first example regrowth layer 524 of FIG. 5 contacts, and/or is located against and/or on the polarization layer 510, the first n-type doped source 514, the first n-type doped drain 516, the second n-type doped source 518, the second n-type doped drain 520, and the isolation structure 522 of FIG. 5. In some examples, the first regrowth layer 524 of FIG. 5 may contact, and/or may be located against and/or on the polarization layer 510, the first n-type doped source 514, the first n-type doped drain 516, the second n-type doped source 518, the second n-type doped drain 520, and the isolation structure 522 of FIG. 5 as a result of the first regrowth layer 524 being deposited, grown, and/or otherwise formed against, on, and/or over the polarization layer 510, the first n-type doped source 514, the first n-type doped drain 516, the second n-type doped source 518, the second n-type doped drain 520, and the isolation structure 522.

In the illustrated example of FIG. 5, the first regrowth layer 524 is formed from and/or made of silicon (Si) and nitrogen (N). For example, the first regrowth layer 524 of FIG. 5 may be formed from and/or made of silicon mononitride (SiN). In other examples, the first regrowth layer 524 of FIG. 5 may alternatively be formed from and/or made of (Si) and oxygen (O). For example, the first regrowth layer 524 of FIG. 5 may be formed from and/or made of silicon dioxide (SiO₂). In other examples, the first regrowth layer 524 of FIG. 5 may alternatively be formed from and/or made of aluminum (Al) and oxygen (O). For example, the first regrowth layer 524 of FIG. 5 may be formed from and/or made of aluminum oxide (Al₂O₃). In other examples, the first regrowth layer 524 of FIG. 5 may be formed from a material other than silicon mononitride, silicon dioxide, or aluminum oxide, and/or may be formed from and/or made of elements and/or materials other than silicon, nitrogen, oxygen, and/or aluminum.

The first example LED structure 526 of FIG. 5 extends through the first regrowth layer 524 of FIG. 5 and partially into the polarization layer 510 of FIG. 5. The first LED structure 526 of FIG. 5 is positioned between the first n-type doped source 514 and the first n-type doped drain 516 of FIG. 5 to receive electrons from the 2DEG 512 of FIG. 5 when the first gate 504 of FIG. 5 is powered and/or turned on (e.g., when a voltage is applied to the first gate 504). The first LED structure 526 of FIG. 5 includes the first example group base 528, the first example quantum well 530 and the first example p-type doped group III-V cap 532 of FIG. 5, as further described below.

The first example group III-V base 528 of FIG. 5 contacts, and/or is located against and/or on the polarization layer 510 of FIG. 5. In some examples, the first group III-V base 528 of FIG. 5 may contact, and/or may be located against and/or on the polarization layer 510 of FIG. 5 as a result of the first group III-V base 528 being deposited, grown, and/or otherwise formed against, on, and/or over the polarization layer 510. In the illustrated example of FIG. 5, the first group base 528 is formed from and/or made of gallium and nitrogen. For example, the first group base 528 of FIG. 5 may be formed from and/or made of gallium nitride (GaN). In other examples, the first group base 528 of FIG. 5 may be formed from and/or made of a group III-V compound including elements and/or materials other than gallium and/or nitrogen.

The first example quantum well 530 of FIG. 5 contacts, and/or is located against and/or on the first group III-V base 528 of FIG. 5. In some examples, the first quantum well 530 of FIG. 5 may contact, and/or may be located against and/or on the first group base 528 of FIG. 5 as a result of the first quantum well 530 being deposited, grown, and/or otherwise formed against, on, and/or over the first group III-V base 528. In the illustrated example of FIG. 5, the first quantum well 530 is formed from and/or made of indium (In), gallium (Ga), and nitrogen (N). For example, the first quantum well 530 of FIG. 5 may be formed from and/or made of indium gallium nitride (InGaN) having a ratio of indium to gallium that is selected based on a desired color of light to be extracted from and/or generated by the first LED structure 526 of FIG. 5. In some examples, the first quantum well 530 may have a ratio of indium to gallium that is approximately thirty percent (30%) indium for blue light, greater than thirty percent (30%) indium for green light, and approximately one hundred percent (100%) indium for red light. In other examples, the first quantum well 530 of FIG. 5 may be formed from and/or made of a material other than indium gallium nitride, and/or may be formed from and/or made of elements and/or materials other than indium, gallium, and/or nitrogen.

The first example p-type doped group III-V cap 532 of FIG. 5 contacts, and/or is located against and/or on the first quantum well 530 of FIG. 5. In some examples, the first p-type doped group III-V cap 532 of FIG. 5 may contact, and/or may be located against and/or on the first quantum well 530 of FIG. 5 as a result of the first p-type doped group III-V cap 532 being deposited, grown, and/or otherwise formed against, on, and/or over the first quantum well 530. In the illustrated example of FIG. 5, the first p-type doped group III-V cap 532 is formed from and/or made of a p-type doped composition of gallium (Ga) and nitrogen (N). For example, the first p-type group III-V cap 532 of FIG. 5 may be formed from and/or made of p-type doped gallium nitride (P-GaN). In other examples, the first p-type doped group III-V cap 532 of FIG. 5 may be formed from and/or made of a p-type doped group III-V compound including elements and/or materials other than gallium and/or nitrogen.

The second example regrowth layer 534 of FIG. 5 contacts, and/or is located against and/or on the first n-type doped source 514, the first n-type doped drain 516, the second n-type doped source 518, the second n-type doped drain 520, the first regrowth layer 524, and the first LED structure 526 (e.g., the first quantum well 530 and/or the first p-type doped group III-V cap 532 of the first LED structure 526) of FIG. 5. In some examples, the second regrowth layer 534 of FIG. 5 may contact, and/or may be located against and/or on the first n-type doped source 514, the first n-type doped drain 516, the second n-type doped source 518, the second n-type doped drain 520, the first regrowth layer 524, and the first LED structure 526 of FIG. 5 as a result of the second regrowth layer 534 being deposited, grown, and/or otherwise formed against, on, and/or over the first n-type doped source 514, the first n-type doped drain 516, the second n-type doped source 518, the second n-type doped drain 520, the first regrowth layer 524, and the first LED structure 526.

In the illustrated example of FIG. 5, the second regrowth layer 534 is formed from and/or made of silicon (Si) and nitrogen (N). For example, the second regrowth layer 534 of FIG. 5 may be formed from and/or made of silicon mononitride (SiN). In other examples, the second regrowth layer 534 of FIG. 5 may alternatively be formed from and/or made of (Si) and oxygen (O). For example, the second regrowth layer 534 of FIG. 5 may be formed from and/or made of silicon dioxide (SiO₂). In other examples, the second regrowth layer 534 of FIG. 5 may alternatively be formed from and/or made of aluminum (Al) and oxygen (O). For example, the second regrowth layer 534 of FIG. 5 may be formed from and/or made of aluminum oxide (Al₂O₃). In other examples, the second regrowth layer 534 of FIG. 5 may be formed from a material other than silicon mononitride, silicon dioxide, or aluminum oxide, and/or may be formed from and/or made of elements and/or materials other than silicon, nitrogen, oxygen, and/or aluminum.

The second example LED structure 536 of FIG. 5 extends through the second regrowth layer 534 and the first regrowth layer 524 of FIG. 5 and partially into the polarization layer 510 of FIG. 5. The second LED structure 536 of FIG. 5 is positioned between the second n-type doped source 518 and the second n-type doped drain 520 of FIG. 5 to receive electrons from the 2DEG 512 of FIG. 5 when the second gate 506 of FIG. 5 is powered and/or turned on (e.g., when a voltage is applied to the second gate 506). The second LED structure 536 of FIG. 5 includes the second example group III-V base 538, the second example quantum well 540 and the second example p-type doped group III-V cap 542 of FIG. 5, as further described below.

The second example group III-V base 538 of FIG. 5 contacts, and/or is located against and/or on the polarization layer 510 of FIG. 5. In some examples, the second group III-V base 538 of FIG. 5 may contact, and/or may be located against and/or on the polarization layer 510 of FIG. 5 as a result of the second group III-V base 538 being deposited, grown, and/or otherwise formed against, on, and/or over the polarization layer 510. In the illustrated example of FIG. 5, the second group III-V base 538 is formed from and/or made of gallium and nitrogen. For example, the second group III-V base 538 of FIG. 5 may be formed from and/or made of gallium nitride (GaN). In other examples, the second group III-V base 538 of FIG. 5 may be formed from and/or made of a group III-V compound including elements and/or materials other than gallium and/or nitrogen.

The second example quantum well 540 of FIG. 5 contacts, and/or is located against and/or on the second group III-V base 538 of FIG. 5. In some examples, the second quantum well 540 of FIG. 5 may contact, and/or may be located against and/or on the second group III-V base 538 of FIG. 5 as a result of the second quantum well 540 being deposited, grown, and/or otherwise formed against, on, and/or over the second group III-V base 538. In the illustrated example of FIG. 5, the second quantum well 540 is formed from and/or made of indium (In), gallium (Ga), and nitrogen (N). For example, the second quantum well 540 of FIG. 5 may be formed from and/or made of indium gallium nitride (InGaN) having a ratio of indium to gallium that is selected based on a desired color of light to be extracted from and/or generated by the second LED structure 536 of FIG. 5. In some examples, the second quantum well 540 may have a ratio of indium to gallium that is approximately thirty percent (30%) indium for blue light, greater than thirty percent (30%) indium for green light, and approximately one hundred percent (100%) indium for red light. In other examples, the second quantum well 540 of FIG. 5 may be formed from and/or made of a material other than indium gallium nitride, and/or may be formed from and/or made of elements and/or materials other than indium, gallium, and/or nitrogen.

In the illustrated example of FIG. 5, the ratio of indium to gallium of the second quantum well 540 of FIG. 5 differs from the ratio of indium to gallium of the first quantum well 530 of FIG. 5 such that the color of light to be extracted from the second LED structure 536 of FIG. 5 differs from the color of light to be extracted from the first LED structure 526 of FIG. 5. In other examples, the ratio of indium to gallium of the second quantum well 540 of FIG. 5 may be approximately the same as the ratio of indium to gallium of the first quantum well 530 of FIG. 5 such that the color of light to be extracted from the second LED structure 536 of FIG. 5 is approximately the same as the color of light to be extracted from the first LED structure 526 of FIG. 5

The second example p-type doped group III-V cap 542 of FIG. 5 contacts, and/or is located against and/or on the second quantum well 540 of FIG. 5. In some examples, the second p-type doped group III-V cap 542 of FIG. 5 may contact, and/or may be located against and/or on the second quantum well 540 of FIG. 5 as a result of the second p-type doped group III-V cap 542 being deposited, grown, and/or otherwise formed against, on, and/or over the second quantum well 540. In the illustrated example of FIG. 5, the second p-type doped group III-V cap 542 is formed from and/or made of a p-type doped composition of gallium (Ga) and nitrogen (N). For example, the second p-type group III-V cap 542 of FIG. 5 may be formed from and/or made of p-type doped gallium nitride (P-GaN). In other examples, the second p-type doped group III-V cap 542 of FIG. 5 may be formed from and/or made of a p-type doped group III-V compound including elements and/or materials other than gallium and/or nitrogen.

The third example regrowth layer 544 of FIG. 5 contacts, and/or is located against and/or on the first LED structure 526 (e.g., the first p-type doped group III-V cap 532 of the first LED structure 526) and the second regrowth layer 534 of FIG. 5. In some examples, the third regrowth layer 544 of FIG. 5 may contact, and/or may be located against and/or on the first LED structure 526 and the second regrowth layer 534 of FIG. 5 as a result of the third regrowth layer 544 being deposited, grown, and/or otherwise formed against, on, and/or over the first LED structure 526 and the second regrowth layer 534.

In the illustrated example of FIG. 5, the third regrowth layer 544 is formed from and/or made of silicon (Si) and nitrogen (N). For example, the third regrowth layer 544 of FIG. 5 may be formed from and/or made of silicon mononitride (SiN). In other examples, the third regrowth layer 544 of FIG. 5 may alternatively be formed from and/or made of (Si) and oxygen (O). For example, the third regrowth layer 544 of FIG. 5 may be formed from and/or made of silicon dioxide (SiO₂). In other examples, the third regrowth layer 544 of FIG. 5 may alternatively be formed from and/or made of aluminum (Al) and oxygen (O). For example, the third regrowth layer 544 of FIG. 5 may be formed from and/or made of aluminum oxide (Al₂O₃). In other examples, the third regrowth layer 544 of FIG. 5 may be formed from a material other than silicon mononitride, silicon dioxide, or aluminum oxide, and/or may be formed from and/or made of elements and/or materials other than silicon, nitrogen, oxygen, and/or aluminum.

The first example source contact 546 of FIG. 5 extends through the third regrowth layer 544 and the second regrowth layer 534 of FIG. 5 and contacts the first n-type doped source 514 of FIG. 5. The first example drain contact 548 of FIG. 5 extends through the third regrowth layer 544 and the second regrowth layer 534 of FIG. 5 and contacts the first n-type doped drain 516 of FIG. 5. The first example LED anode contact 550 of FIG. 5 extends through the third regrowth layer 544 of FIG. 5 and contacts the first p-type doped group III-V cap 532 of the first LED structure 526 of FIG. 5. The second example source contact 552 of FIG. 5 extends through the third regrowth layer 544 and the second regrowth layer 534 of FIG. 5 and contacts the second n-type doped source 518 of FIG. 5. The second example drain contact 554 of FIG. 5 extends through the third regrowth layer 544 and the second regrowth layer 534 of FIG. 5 and contacts the second n-type doped drain 520 of FIG. 5. The second example LED anode contact 556 of FIG. 5 contacts the second p-type doped group III-V cap 542 of the second LED structure 536 of FIG. 5.

In the illustrated example of FIG. 5, the first source contact 546, the first drain contact 548, the first LED anode contact 550, the second source contact 552, the second drain contact 554, and the second LED anode contact 556 are respectively formed from and/or made of one or more transparent and/or translucent metal material(s). Fabrication of the first source contact 546, the first drain contact 548, the first LED anode contact 550, the second source contact 552, the second drain contact 554, and the second LED anode contact 556 of FIG. 5 from transparent and/or translucent metal materials advantageously allows for light extraction from the topside of the substrate-gated group III-V transistor 500 of FIG. 5. In some examples, the first source contact 546, the first drain contact 548, the first LED anode contact 550, the second source contact 552, the second drain contact 554, and/or the second LED anode contact 556 of FIG. 5 may respectively be formed from and/or made of indium tin oxide (ITO). In other examples, the first source contact 546, the first drain contact 548, the first LED anode contact 550, the second source contact 552, the second drain contact 554, and/or the second LED anode contact 556 of FIG. 5 may respectively be formed from and/or made of a transparent and/or translucent metal material other than indium tin oxide (ITO). In still other examples, the first source contact 546, the first drain contact 548, the first LED anode contact 550, the second source contact 552, the second drain contact 554, and the second LED anode contact 556 of FIG. 5 may respectively be formed from and/or made of a material other than a transparent and/or translucent metal material.

The example ILD layer 558 of FIG. 5 contacts, and/or is located against and/or on the second LED structure 536 (e.g., the second p-type doped group III-V cap 542 of the second LED structure 536), the third regrowth layer 544, the first source contact 546, the first drain contact 548, the first LED anode contact 550, the second source contact 552, the second drain contact 554, and the second LED anode contact 556 of FIG. 5. In some examples, the ILD layer 558 of FIG. 5 may contact, and/or may be located against and/or on the second LED structure 536, the third regrowth layer 544, the first source contact 546, the first drain contact 548, the first LED anode contact 550, the second source contact 552, the second drain contact 554, and the second LED anode contact 556 of FIG. 5 as a result of the ILD layer 558 being deposited, grown, and/or otherwise formed against, on, and/or over the second LED structure 536, the third regrowth layer 544, the first source contact 546, the first drain contact 548, the first LED anode contact 550, the second source contact 552, the second drain contact 554, and the second LED anode contact 556. In the illustrated example of FIG. 5, the ILD layer 558 is formed from and/or made of silicon (Si) and oxygen (O). For example, the ILD layer 558 of FIG. 5 may be formed from and/or made of silicon dioxide (Sift). In other examples, the ILD layer 558 of FIG. 5 may be formed from and/or made of a material other than silicon dioxide, and/or may be formed from and/or made of elements and/or materials other than silicon and oxygen.

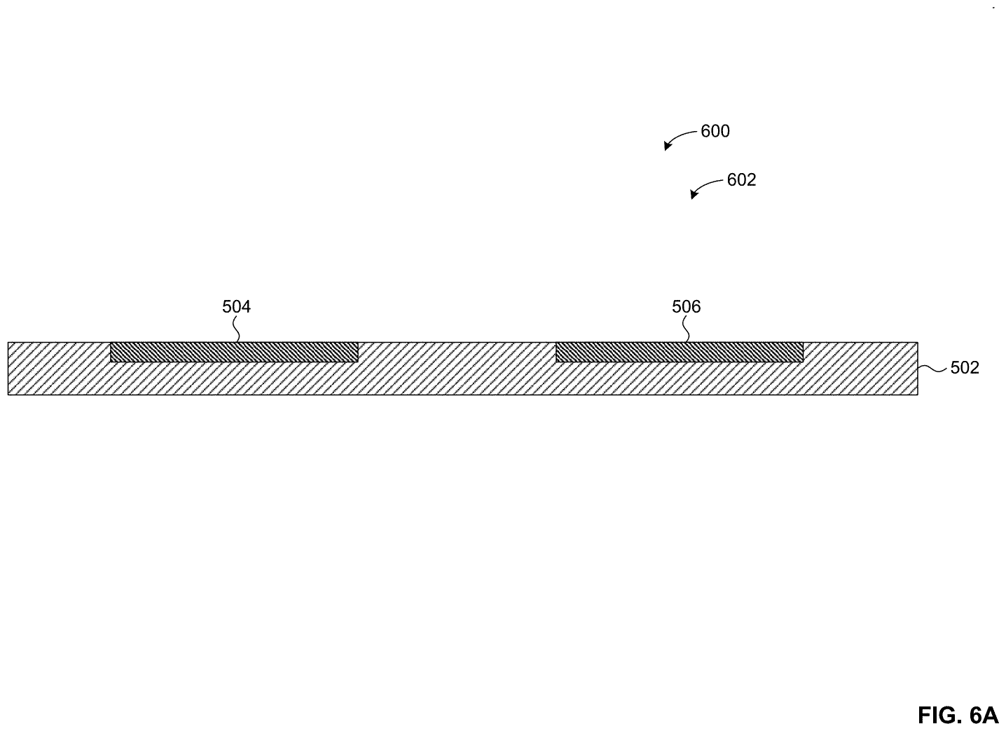

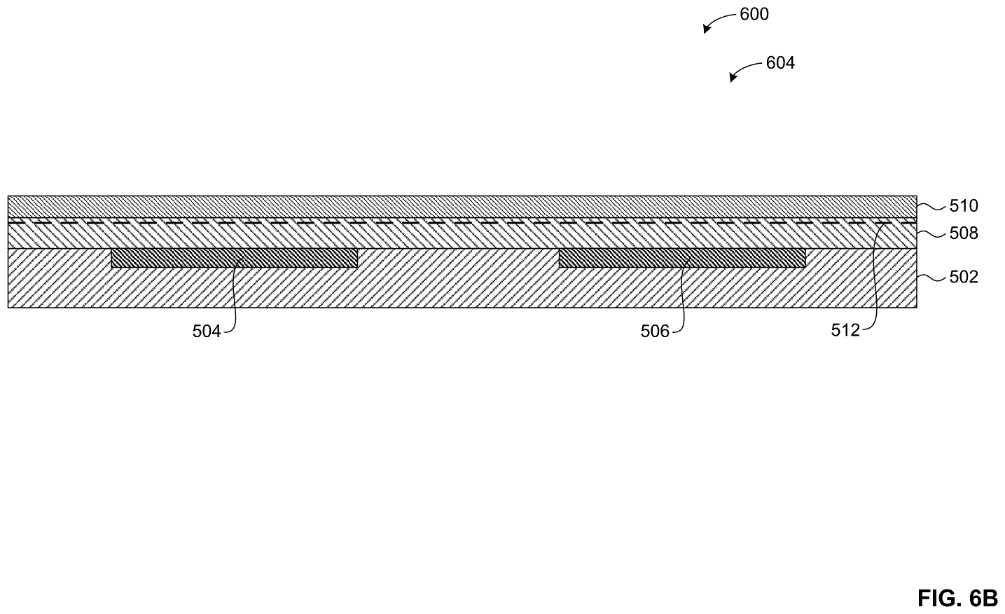

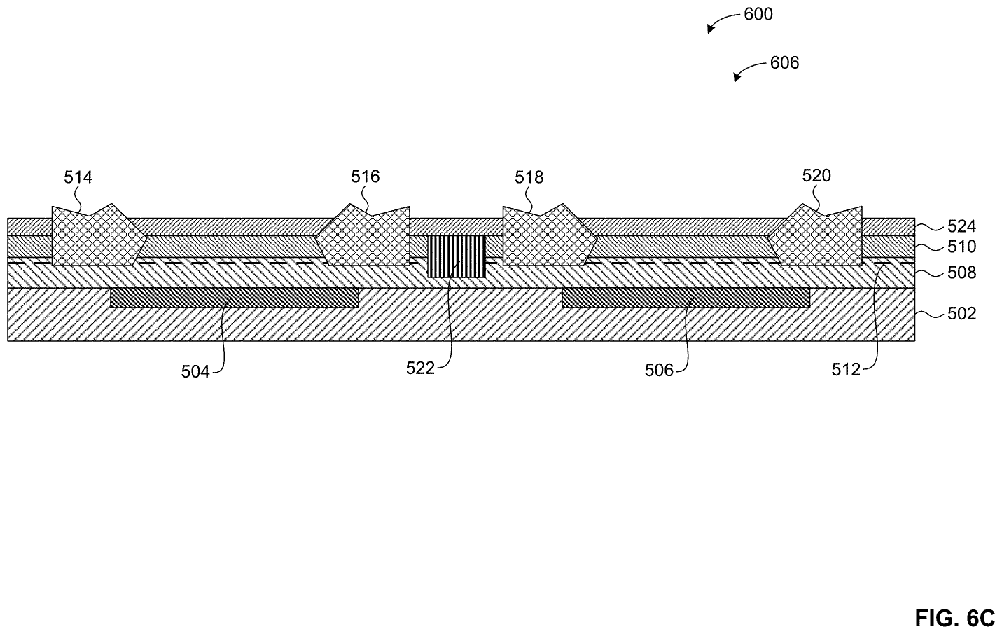

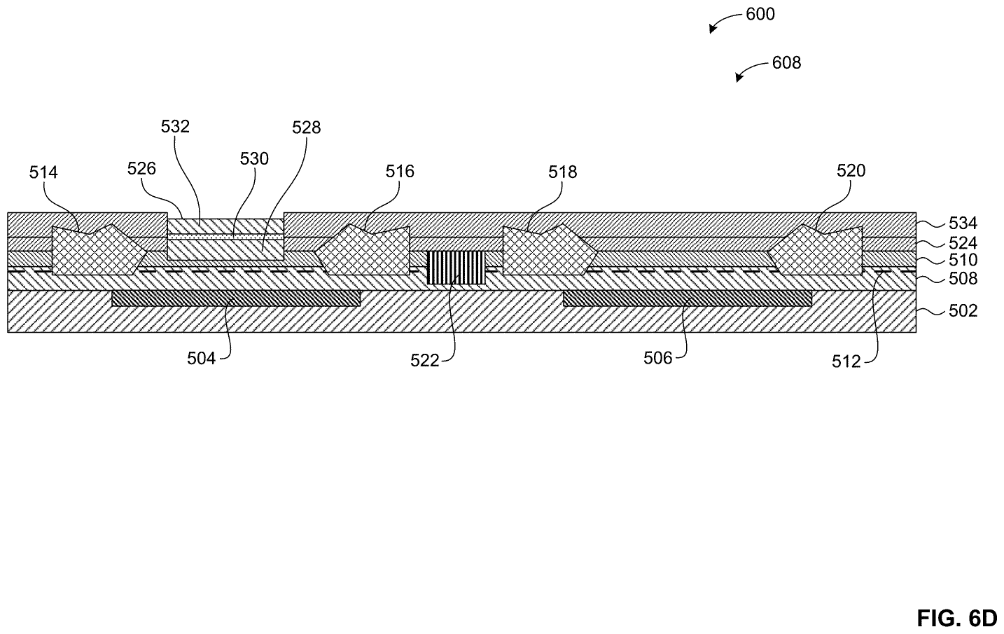

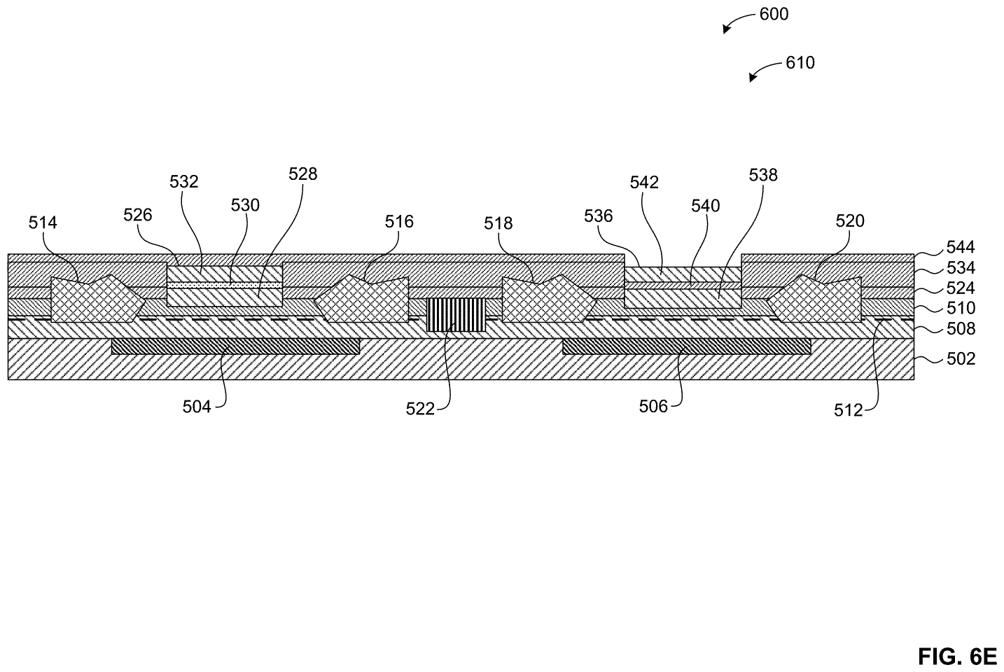

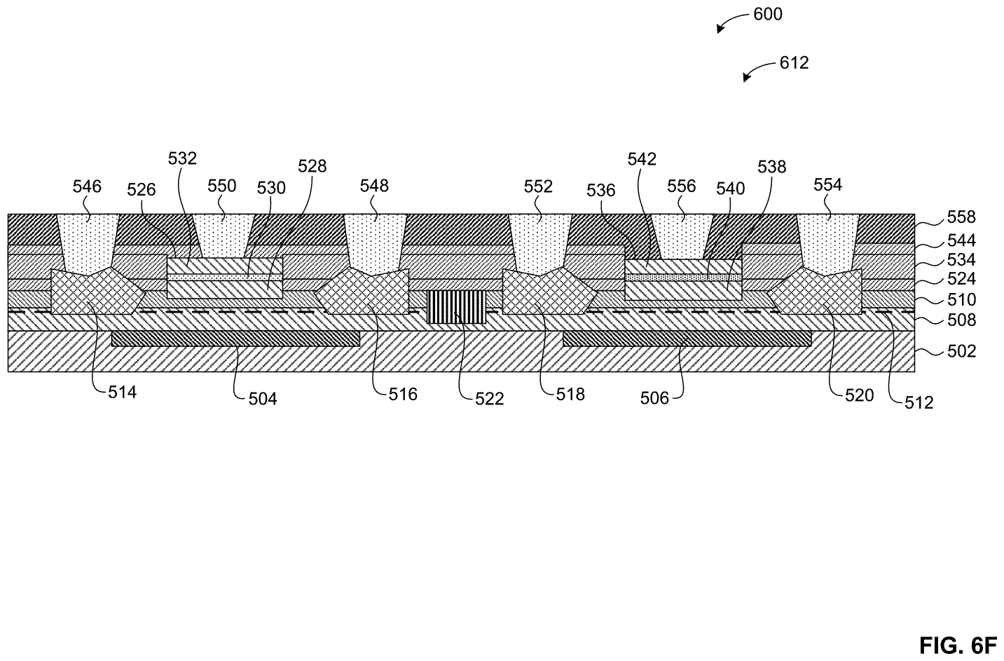

FIGS. 6A-6F illustrate an example fabrication process 600 for the second example substrate-gated group III-V transistor 500 of FIG. 5. FIG. 6A illustrates a first example phase 602 of the fabrication process 600. As shown in the illustrated example of FIG. 6A, the first phase 602 of the fabrication process 600 includes forming and/or locating the first gate 504 and the second gate 506 of FIG. 5 against and/or on the substrate 502 of FIG. 5. For example, the first gate 504 and the second gate 506 of FIG. 5 may contact, and/or may be located against and/or on the substrate 502 of FIG. 5 as a result of the first gate 504 and the second gate 506 being deposited, grown, and/or otherwise formed against, on, and/or over the substrate 502 in connection with the first phase 602 of FIG. 6A.

FIG. 6B illustrates a second example phase 604 of the fabrication process 600 to be performed subsequent to the first phase 602 of the fabrication process 600. As shown in the illustrated example of FIG. 6B, the second phase 604 of the fabrication process 600 includes forming and/or locating the group III-V layer 508 of FIG. 5 against and/or on the substrate 502, the first gate 504, and the second gate 506 of FIG. 5. For example, the group III-V layer 508 of FIG. 5 may contact, and/or may be located against and/or on the substrate 502, the first gate 504, and the second gate 506 of FIG. 5 as a result of the group III-V layer 508 being deposited, grown, and/or otherwise formed against, on, and/or over the substrate 502, the first gate 504, and the second gate 506 in connection with the second phase 604 of FIG. 6B.

As further shown in the illustrated example of FIG. 6B, the second phase 604 of the fabrication process 600 also includes forming and/or locating the polarization layer 510 of FIG. 5 against and/or on the group III-V layer 508 of FIG. 5 to generate the 2DEG 512 of FIG. 5. For example, the polarization layer 510 of FIG. 5 may contact, and/or may be located against and/or on the group III-V layer 508 of FIG. 5 as a result of the polarization layer 510 being deposited, grown, and/or otherwise formed against, on, and/or over the group III-V layer 508 in connection with the second phase 604 of FIG. 6B.

FIG. 6C illustrates a third example phase 606 of the fabrication process 600 to be performed subsequent to the second phase 604 of the fabrication process 600. As shown in the illustrated example of FIG. 6C, the third phase 606 of the fabrication process 600 includes forming and/or locating the first n-type doped source 514, the first n-type doped drain 516, the second n-type doped source 518, and the second n-type doped drain 520 of FIG. 5 against and/or on the group III-V layer 508 of FIG. 5 such that the first n-type doped source 514, the first n-type doped drain 516, the second n-type doped source 518, and the second n-type doped drain 520 extend through the polarization layer 510 of FIG. 5 and partially into the group III-V layer 508 to contact the 2DEG 512 of FIG. 5. For example, the first n-type doped source 514, the first n-type doped drain 516, the second n-type doped source 518, and the second n-type doped drain 520 of FIG. 2 may contact, and/or may be located against and/or on the 2DEG 512 of the group III-V layer 508 of FIG. 5 as a result of the first n-type doped source 514, the first n-type doped drain 516, the second n-type doped source 518, and the second n-type doped drain 520 being deposited, grown, and/or otherwise formed against, on, and/or over the group III-V layer 508 in connection with the third phase 606 of FIG. 6C.

As further shown in the illustrated example of FIG. 6C, the third phase 606 of the fabrication process 600 also includes forming and/or locating the isolation structure 522 of FIG. 5 against and/or on the group III-V layer 508 of FIG. 5 such that the isolation structure 522 extends through the polarization layer 510 of FIG. 5 and partially into the group III-V layer 508 to block the 2DEG 512 of FIG. 5. For example, the isolation structure 522 of FIG. 5 may contact, and/or may be located against and/or on the group III-V layer 508 of FIG. 5 to block the 2DEG 512 of FIG. 5 as a result of the isolation structure 522 being deposited, grown, and/or otherwise formed against, on, and/or over the group III-V layer 508 in connection with the third phase 606 of FIG. 6C.

As further shown in the illustrated example of FIG. 6C, the third phase 606 of the fabrication process 600 also includes forming and/or locating the first regrowth layer 524 of FIG. 5 against and/or on the polarization layer 510, the first n-type doped source 514, the first n-type doped drain 516, the second n-type doped source 518, the second n-type doped drain 520, and the isolation structure 522 of FIG. 5. For example, the first regrowth layer 524 of FIG. 5 may contact, and/or may be located against and/or on the polarization layer 510, the first n-type doped source 514, the first n-type doped drain 516, the second n-type doped source 518, the second n-type doped drain 520, and the isolation structure 522 of FIG. 5 as a result of the first regrowth layer 524 being deposited, grown, and/or otherwise formed against, on, and/or over the polarization layer 510, the first n-type doped source 514, the first n-type doped drain 516, the second n-type doped source 518, the second n-type doped drain 520, and the isolation structure 522 in connection with the third phase 606 of FIG. 6C.

FIG. 6D illustrates a fourth example phase 608 of the fabrication process 600 to be performed subsequent to the third phase 606 of the fabrication process 600. As shown in the illustrated example of FIG. 6D, the fourth phase 608 of the fabrication process 600 includes forming and/or locating the first LED structure 526 of FIG. 5 against and/or on the polarization layer 510 of FIG. 5 such that the first LED structure 526 extends through the first regrowth layer 524 of FIG. 5 and partially into the polarization layer 510. For example, the first LED structure 526 of FIG. 5 may contact, and/or may be located against and/or on the polarization layer 510 of FIG. 5 as a result of the first LED structure 526 being deposited, grown, and/or otherwise formed against, on, and/or over the polarization layer 510 in connection with the fourth phase 608 of FIG. 6D. In some examples, the first group III-V base 528 of the first LED structure 526 of FIG. 5 may be deposited, grown, and/or otherwise formed against, on, and/or over the polarization layer 510, the first quantum well 530 of the first LED structure 526 of FIG. 5 may be deposited, grown, and/or otherwise formed against, on, and/or over the first group III-V base 528, and the first p-type doped group III-V cap 532 of the first LED structure 526 of FIG. 5 may be deposited, grown, and/or otherwise formed against, on, and/or over the first quantum well 530 in connection with the fourth phase 608 of FIG. 6D.

As further shown in the illustrated example of FIG. 6D, the fourth phase 608 of the fabrication process 600 also includes forming and/or locating the second regrowth layer 534 of FIG. 5 against and/or on the first n-type doped source 514, the first n-type doped drain 516, the second n-type doped source 518, the second n-type doped drain 520, the first regrowth layer 524, and the first LED structure 526 (e.g., the first quantum well 530 and/or the first p-type doped group III-V cap 532 of the first LED structure 526) of FIG. 5. For example, the second regrowth layer 534 of FIG. 5 may contact, and/or may be located against and/or on the first n-type doped source 514, the first n-type doped drain 516, the second n-type doped source 518, the second n-type doped drain 520, the first regrowth layer 524, and the first LED structure 526 of FIG. 5 as a result of the second regrowth layer 534 being deposited, grown, and/or otherwise formed against, on, and/or over the first n-type doped source 514, the first n-type doped drain 516, the second n-type doped source 518, the second n-type doped drain 520, the first regrowth layer 524, and the first LED structure 526 in connection with the fourth phase 608 of FIG. 6D.

FIG. 6E illustrates a fifth example phase 610 of the fabrication process 600 to be performed subsequent to the fourth phase 608 of the fabrication process 600. As shown in the illustrated example of FIG. 6E, the fifth phase 610 of the fabrication process 600 includes forming and/or locating the second LED structure 536 of FIG. 5 against and/or on the polarization layer 510 of FIG. 5 such that the second LED structure 536 extends through the second regrowth layer 534 and the first regrowth layer 524 of FIG. 5 and partially into the polarization layer 510. For example, the second LED structure 536 of FIG. 5 may contact, and/or may be located against and/or on the polarization layer 510 of FIG. 5 as a result of the second LED structure 536 being deposited, grown, and/or otherwise formed against, on, and/or over the polarization layer 510 in connection with the fifth phase 610 of FIG. 6E. In some examples, the second group III-V base 538 of the second LED structure 536 of FIG. 5 may be deposited, grown, and/or otherwise formed against, on, and/or over the polarization layer 510, the second quantum well 540 of the second LED structure 536 of FIG. 5 may be deposited, grown, and/or otherwise formed against, on, and/or over the second group III-V base 538, and the second p-type doped group III-V cap 542 of the second LED structure 536 of FIG. 5 may be deposited, grown, and/or otherwise formed against, on, and/or over the second quantum well 540 in connection with the fifth phase 610 of FIG. 6E.

As further shown in the illustrated example of FIG. 6E, the fifth phase 610 of the fabrication process 600 also includes forming and/or locating the third regrowth layer 544 of FIG. 5 against and/or on the first LED structure 526 (e.g., the first p-type doped group III-V cap 532 of the first LED structure 526) and the second regrowth layer 534 of FIG. 5. For example, the third regrowth layer 544 of FIG. 5 may contact, and/or may be located against and/or on the first LED structure 526 and the second regrowth layer 534 of FIG. 5 as a result of the third regrowth layer 544 being deposited, grown, and/or otherwise formed against, on, and/or over the first LED structure 526 and the second regrowth layer 534 in connection with the fifth phase 610 of FIG. 6E.

FIG. 6F illustrates a sixth example phase 612 of the fabrication process 600 to be performed subsequent to the fifth phase 610 of the fabrication process 600. As shown in the illustrated example of FIG. 6F, the sixth phase 612 of the fabrication process 600 includes forming and/or locating the first source contact 546 of FIG. 5 against and/or on the first n-type doped source 514 of FIG. 5 such that the first source contact 546 extends through the third regrowth layer 544 and the second regrowth layer 534 of FIG. 5 to contact the first n-type doped source 514. For example, the first source contact 546 of FIG. 5 may contact, and/or may be located against and/or on the first n-type doped source 514 of FIG. 5 as a result of the first source contact 546 being deposited, grown, and/or otherwise formed against, on, and/or over the first n-type doped source 514 in connection with the sixth phase 612 of FIG. 6F.

As further shown in the illustrated example of FIG. 6F, the sixth phase 612 of the fabrication process 600 also includes forming and/or locating the first drain contact 548 of FIG. 5 against and/or on the first n-type doped drain 516 of FIG. 5 such that the first drain contact 548 extends through the third regrowth layer 544 and the second regrowth layer 534 of FIG. 5 to contact the first n-type doped drain 516. For example, the first drain contact 548 of FIG. 5 may contact, and/or may be located against and/or on the first n-type doped drain 516 of FIG. 5 as a result of the first drain contact 548 being deposited, grown, and/or otherwise formed against, on, and/or over the first n-type doped drain 516 in connection with the sixth phase 612 of FIG. 6F.

As further shown in the illustrated example of FIG. 6F, the sixth phase 612 of the fabrication process 600 also includes forming and/or locating the first LED anode contact 550 of FIG. 5 against and/or on the first LED structure 526 (e.g., the first p-type doped group III-V cap 532 of the first LED structure 526) of FIG. 5 such that the first LED anode contact 550 extends through the third regrowth layer 544 of FIG. 5 to contact the first LED structure 526. For example, the first LED anode contact 550 of FIG. 5 may contact, and/or may be located against and/or on the first LED structure 526 of FIG. 5 as a result of the first LED anode contact 550 being deposited, grown, and/or otherwise formed against, on, and/or over the first LED structure 526 in connection with the sixth phase 612 of FIG. 6F.

As further shown in the illustrated example of FIG. 6F, the sixth phase 612 of the fabrication process 600 also includes forming and/or locating the second source contact 552 of FIG. 5 against and/or on the second n-type doped source 518 of FIG. 5 such that the second source contact 552 extends through the third regrowth layer 544 and the second regrowth layer 534 of FIG. 5 to contact the second n-type doped source 518. For example, the second source contact 552 of FIG. 5 may contact, and/or may be located against and/or on the second n-type doped source 518 of FIG. 5 as a result of the second source contact 552 being deposited, grown, and/or otherwise formed against, on, and/or over the second n-type doped source 518 in connection with the sixth phase 612 of FIG. 6F.

As further shown in the illustrated example of FIG. 6F, the sixth phase 612 of the fabrication process 600 also includes forming and/or locating the second drain contact 554 of FIG. 5 against and/or on the second n-type doped drain 520 of FIG. 5 such that the second drain contact 554 extends through the third regrowth layer 544 and the second regrowth layer 534 of FIG. 5 to contact the second n-type doped drain 520. For example, the second drain contact 554 of FIG. 5 may contact, and/or may be located against and/or on the second n-type doped drain 520 of FIG. 5 as a result of the second drain contact 554 being deposited, grown, and/or otherwise formed against, on, and/or over the second n-type doped drain 520 in connection with the sixth phase 612 of FIG. 6F.

As further shown in the illustrated example of FIG. 6F, the sixth phase 612 of the fabrication process 600 also includes forming and/or locating the second LED anode contact 556 of FIG. 5 against and/or on the second LED structure 536 (e.g., the second p-type doped group III-V cap 542 of the second LED structure 536) of FIG. 5. For example, the second LED anode contact 556 of FIG. 5 may contact, and/or may be located against and/or on the second LED structure 536 of FIG. 5 as a result of the second LED anode contact 556 being deposited, grown, and/or otherwise formed against, on, and/or over the second LED structure 536 in connection with the sixth phase 612 of FIG. 6F.

As further shown in the illustrated example of FIG. 6F, the sixth phase 612 of the fabrication process 600 also includes forming and/or locating the ILD layer 558 of FIG. 5 against and/or on the second LED structure 536 (e.g., the second p-type doped group III-V cap 542 of the second LED structure 536), the third regrowth layer 544, the first source contact 546, the first drain contact 548, the first LED anode contact 550, the second source contact 552, the second drain contact 554, and the second LED anode contact 556 of FIG. 5. For example, the ILD layer 558 of FIG. 5 may contact, and/or may be located against and/or on the second LED structure 536, the third regrowth layer 544, the first source contact 546, the first drain contact 548, the first LED anode contact 550, the second source contact 552, the second drain contact 554, and the second LED anode contact 556 of FIG. 5 as a result of the ILD layer 558 being deposited, grown, and/or otherwise formed against, on, and/or over the second LED structure 536, the third regrowth layer 544, the first source contact 546, the first drain contact 548, the first LED anode contact 550, the second source contact 552, the second drain contact 554, and the second LED anode contact 556 in connection with the sixth phase 612 of FIG. 6F.

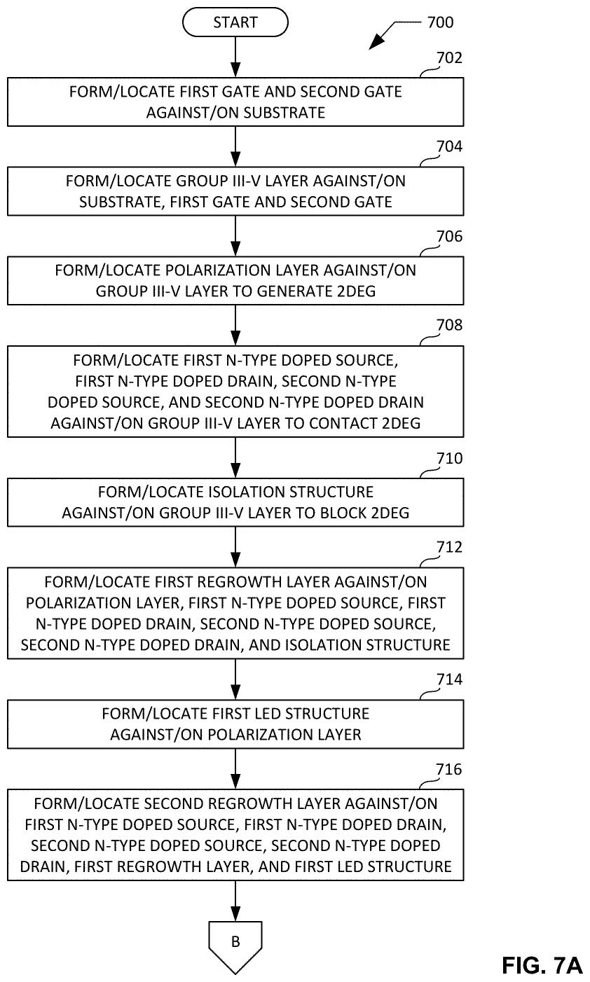

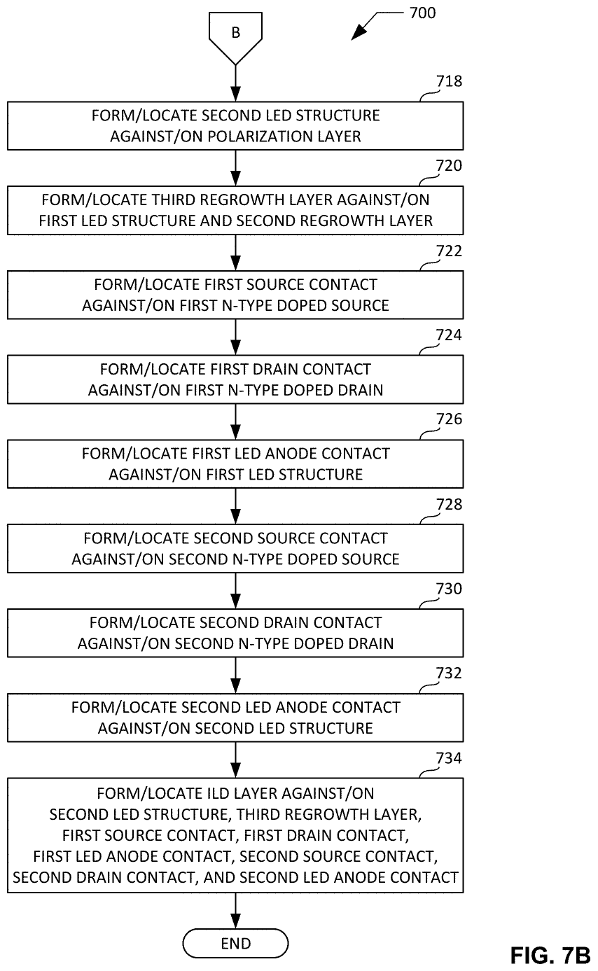

FIGS. 7A and 7B are a flowchart representative of an example method 700 for fabricating the second example substrate-gated group III-V transistor 500 of FIGS. 5 and 6A-6F. The example method 700 of FIGS. 7A and 7B includes forming and/or locating the first gate 504 and the second gate 506 of FIG. 5 against and/or on the substrate 502 of FIG. 5 (block 702). For example, the first gate 504 and the second gate 506 of FIG. 5 may contact, and/or may be located against and/or on the substrate 502 of FIG. 5 as a result of the first gate 504 and the second gate 506 being deposited, grown, and/or otherwise formed against, on, and/or over the substrate 502, as described above in connection with the first phase 602 of FIG. 6A.

The example method 700 of FIGS. 7A and 7B also includes forming and/or locating the group III-V layer 508 of FIG. 5 against and/or on the substrate 502, the first gate 504, and the second gate 506 of FIG. 5 (block 704). For example, the group III-V layer 508 of FIG. 5 may contact, and/or may be located against and/or on the substrate 502, the first gate 504, and the second gate 506 of FIG. 5 as a result of the group III-V layer 508 being deposited, grown, and/or otherwise formed against, on, and/or over the substrate 502, the first gate 504, and the second gate 506, as described above in connection with the second phase 604 of FIG. 6B.

The example method 700 of FIGS. 7A and 7B also includes forming and/or locating the polarization layer 510 of FIG. 5 against and/or on the group III-V layer 508 of FIG. 5 to generate the 2DEG 512 of FIG. 5 (block 706). For example, the polarization layer 510 of FIG. 5 may contact, and/or may be located against and/or on the group III-V layer 508 of FIG. 5 as a result of the polarization layer 510 being deposited, grown, and/or otherwise formed against, on, and/or over the group III-V layer 508, as described above in connection with the second phase 604 of FIG. 6B.

The example method 700 of FIGS. 7A and 7B also includes forming and/or locating the first n-type doped source 514, the first n-type doped drain 516, the second n-type doped source 518, and the second n-type doped drain 520 of FIG. 5 against and/or on the group III—V layer 508 of FIG. 5 such that the first n-type doped source 514, the first n-type doped drain 516, the second n-type doped source 518, and the second n-type doped drain 520 contact the 2DEG 512 of FIG. 5 (block 708). For example, the first n-type doped source 514, the first n-type doped drain 516, the second n-type doped source 518, and the second n-type doped drain 520 of FIG. 2 may contact, and/or may be located against and/or on the 2DEG 512 of the group III-V layer 508 of FIG. 5 as a result of the first n-type doped source 514, the first n-type doped drain 516, the second n-type doped source 518, and the second n-type doped drain 520 being deposited, grown, and/or otherwise formed against, on, and/or over the group III-V layer 508, as described above in connection with the third phase 606 of FIG. 6C.

The example method 700 of FIGS. 7A and 7B also includes forming and/or locating the isolation structure 522 of FIG. 5 against and/or on the group III-V layer 508 of FIG. 5 such that the isolation structure 522 blocks the 2DEG 512 of FIG. 5 (block 710). For example, the isolation structure 522 of FIG. 5 may contact, and/or may be located against and/or on the group III-V layer 508 of FIG. 5 to block the 2DEG 512 of FIG. 5 as a result of the isolation structure 522 being deposited, grown, and/or otherwise formed against, on, and/or over the group III-V layer 508 in connection with the third phase 606 of FIG. 6C.

The example method 700 of FIGS. 7A and 7B also includes forming and/or locating the first regrowth layer 524 of FIG. 5 against and/or on the polarization layer 510, the first n-type doped source 514, the first n-type doped drain 516, the second n-type doped source 518, the second n-type doped drain 520, and the isolation structure 522 of FIG. 5 (block 712). For example, the first regrowth layer 524 of FIG. 5 may contact, and/or may be located against and/or on the polarization layer 510, the first n-type doped source 514, the first n-type doped drain 516, the second n-type doped source 518, the second n-type doped drain 520, and the isolation structure 522 of FIG. 5 as a result of the first regrowth layer 524 being deposited, grown, and/or otherwise formed against, on, and/or over the polarization layer 510, the first n-type doped source 514, the first n-type doped drain 516, the second n-type doped source 518, the second n-type doped drain 520, and the isolation structure 522, as described above in connection with the third phase 606 of FIG. 6C.

The example method 700 of FIGS. 7A and 7B also includes forming and/or locating the first LED structure 526 of FIG. 5 against and/or on the polarization layer 510 of FIG. 5 (block 714). For example, the first LED structure 526 of FIG. 5 may contact, and/or may be located against and/or on the polarization layer 510 of FIG. 5 as a result of the first LED structure 526 being deposited, grown, and/or otherwise formed against, on, and/or over the polarization layer 510 in connection with the fourth phase 608 of FIG. 6D.

The example method 700 of FIGS. 7A and 7B also includes forming and/or locating the second regrowth layer 534 of FIG. 5 against and/or on the first n-type doped source 514, the first n-type doped drain 516, the second n-type doped source 518, the second n-type doped drain 520, the first regrowth layer 524, and the first LED structure 526 (e.g., the first quantum well 530 and/or the first p-type doped group III-V cap 532 of the first LED structure 526) of FIG. 5 (block 716). For example, the second regrowth layer 534 of FIG. 5 may contact, and/or may be located against and/or on the first n-type doped source 514, the first n-type doped drain 516, the second n-type doped source 518, the second n-type doped drain 520, the first regrowth layer 524, and the first LED structure 526 of FIG. 5 as a result of the second regrowth layer 534 being deposited, grown, and/or otherwise formed against, on, and/or over the first n-type doped source 514, the first n-type doped drain 516, the second n-type doped source 518, the second n-type doped drain 520, the first regrowth layer 524, and the first LED structure 526, as described above in connection with the fourth phase 608 of FIG. 6D.

The example method 700 of FIGS. 7A and 7B also includes forming and/or locating the second LED structure 536 of FIG. 5 against and/or on the polarization layer 510 of FIG. 5 (block 718). For example, the second LED structure 536 of FIG. 5 may contact, and/or may be located against and/or on the polarization layer 510 of FIG. 5 as a result of the second LED structure 536 being deposited, grown, and/or otherwise formed against, on, and/or over the polarization layer 510 in connection with the fifth phase 610 of FIG. 6E.

The example method 700 of FIGS. 7A and 7B also includes forming and/or locating the third regrowth layer 544 of FIG. 5 against and/or on the first LED structure 526 (e.g., the first p-type doped group III-V cap 532 of the first LED structure 526) and the second regrowth layer 534 of FIG. 5 (block 720). For example, the third regrowth layer 544 of FIG. 5 may contact, and/or may be located against and/or on the first LED structure 526 and the second regrowth layer 534 of FIG. 5 as a result of the third regrowth layer 544 being deposited, grown, and/or otherwise formed against, on, and/or over the first LED structure 526 and the second regrowth layer 534, as described above in connection with the fifth phase 610 of FIG. 6E.

The example method 700 of FIGS. 7A and 7B also includes forming and/or locating the first source contact 546 of FIG. 5 against and/or on the first n-type doped source 514 of FIG. 5 (block 722). For example, the first source contact 546 of FIG. 5 may contact, and/or may be located against and/or on the first n-type doped source 514 of FIG. 5 as a result of the first source contact 546 being deposited, grown, and/or otherwise formed against, on, and/or over the first n-type doped source 514, as described above in connection with the sixth phase 612 of FIG. 6F.

The example method 700 of FIGS. 7A and 7B also includes forming and/or locating the first drain contact 548 of FIG. 5 against and/or on the first n-type doped drain 516 of FIG. 5 (block 724). For example, the first drain contact 548 of FIG. 5 may contact, and/or may be located against and/or on the first n-type doped drain 516 of FIG. 5 as a result of the first drain contact 548 being deposited, grown, and/or otherwise formed against, on, and/or over the first n-type doped drain 516, as described above in connection with the sixth phase 612 of FIG. 6F.

The example method 700 of FIGS. 7A and 7B also includes forming and/or locating the first LED anode contact 550 of FIG. 5 against and/or on the first LED structure 526 (e.g., the first p-type doped group III-V cap 532 of the first LED structure 526) of FIG. 5 (block 726). For example, the first LED anode contact 550 of FIG. 5 may contact, and/or may be located against and/or on the first LED structure 526 of FIG. 5 as a result of the first LED anode contact 550 being deposited, grown, and/or otherwise formed against, on, and/or over the first LED structure 526, as described above in connection with the sixth phase 612 of FIG. 6F.

The example method 700 of FIGS. 7A and 7B also includes forming and/or locating the second source contact 552 of FIG. 5 against and/or on the second n-type doped source 518 of FIG. 5 (block 728). For example, the second source contact 552 of FIG. 5 may contact, and/or may be located against and/or on the second n-type doped source 518 of FIG. 5 as a result of the second source contact 552 being deposited, grown, and/or otherwise formed against, on, and/or over the second n-type doped source 518, as described above in connection with the sixth phase 612 of FIG. 6F.

The example method 700 of FIGS. 7A and 7B also includes forming and/or locating the second drain contact 554 of FIG. 5 against and/or on the second n-type doped drain 520 of FIG. 5 (block 730). For example, the second drain contact 554 of FIG. 5 may contact, and/or may be located against and/or on the second n-type doped drain 520 of FIG. 5 as a result of the second drain contact 554 being deposited, grown, and/or otherwise formed against, on, and/or over the second n-type doped drain 520, as described above in connection with the sixth phase 612 of FIG. 6F.

The example method 700 of FIGS. 7A and 7B also includes forming and/or locating the second LED anode contact 556 of FIG. 5 against and/or on the second LED structure 536 (e.g., the second p-type doped group III-V cap 542 of the second LED structure 536) of FIG. 5 (block 732). For example, the second LED anode contact 556 of FIG. 5 may contact, and/or may be located against and/or on the second LED structure 536 of FIG. 5 as a result of the second LED anode contact 556 being deposited, grown, and/or otherwise formed against, on, and/or over the second LED structure 536, as described above in connection with the sixth phase 612 of FIG. 6F.

The example method 700 of FIGS. 7A and 7B also includes forming and/or locating the ILD layer 558 of FIG. 5 against and/or on the second LED structure 536 (e.g., the second p-type doped group III-V cap 542 of the second LED structure 536), the third regrowth layer 544, the first source contact 546, the first drain contact 548, the first LED anode contact 550, the second source contact 552, the second drain contact 554, and the second LED anode contact 556 of FIG. 5 (block 734). For example, the ILD layer 558 of FIG. 5 may contact, and/or may be located against and/or on the second LED structure 536, the third regrowth layer 544, the first source contact 546, the first drain contact 548, the first LED anode contact 550, the second source contact 552, the second drain contact 554, and the second LED anode contact 556 of FIG. 5 as a result of the ILD layer 558 being deposited, grown, and/or otherwise formed against, on, and/or over the second LED structure 536, the third regrowth layer 544, the first source contact 546, the first drain contact 548, the first LED anode contact 550, the second source contact 552, the second drain contact 554, and the second LED anode contact 556, as described above in connection with the sixth phase 612 of FIG. 6F. Following block 734, the example method 700 of FIGS. 7A and 7B ends.

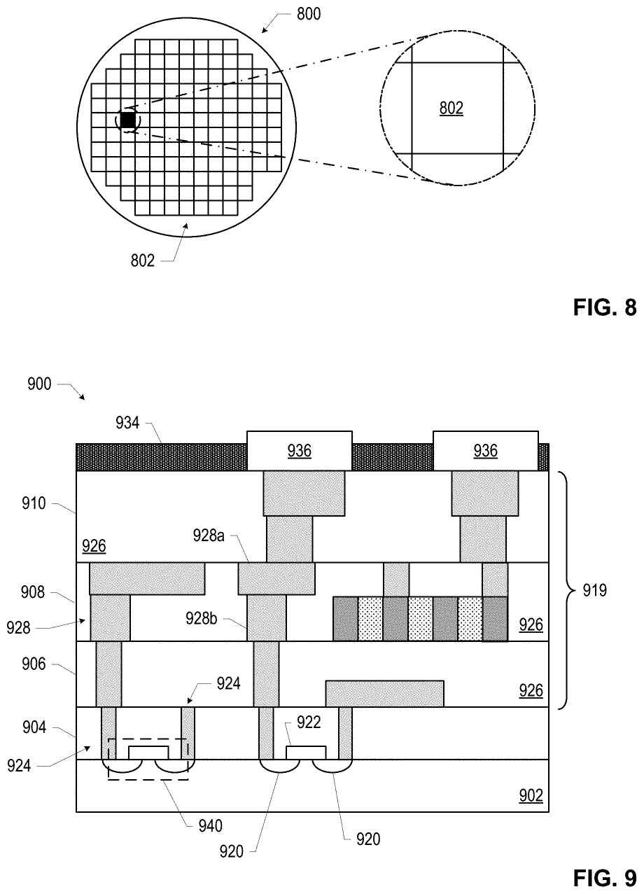

The example substrate-gated group III-V transistors disclosed herein may be included in any suitable electronic component. FIGS. 8-12 illustrate various examples of apparatuses that may include any of the example substrate-gated group III-V transistors disclosed herein (e.g., one or more of the first example substrate-gated group III-V transistor 200 of FIG. 2, and/or one or more of the second example substrate-gated group III-V transistor 500 of FIG. 5).

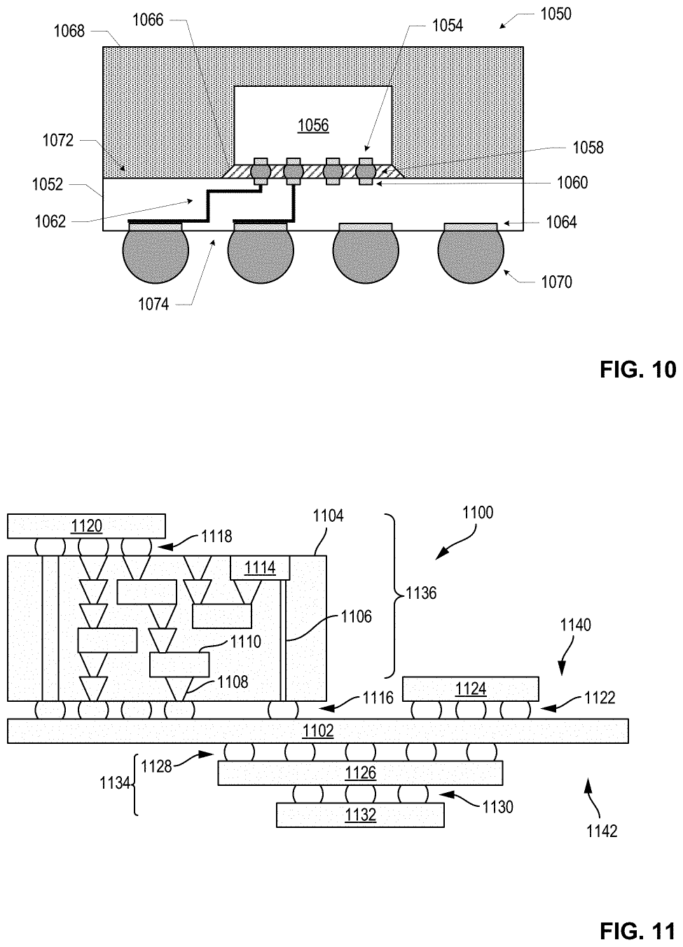

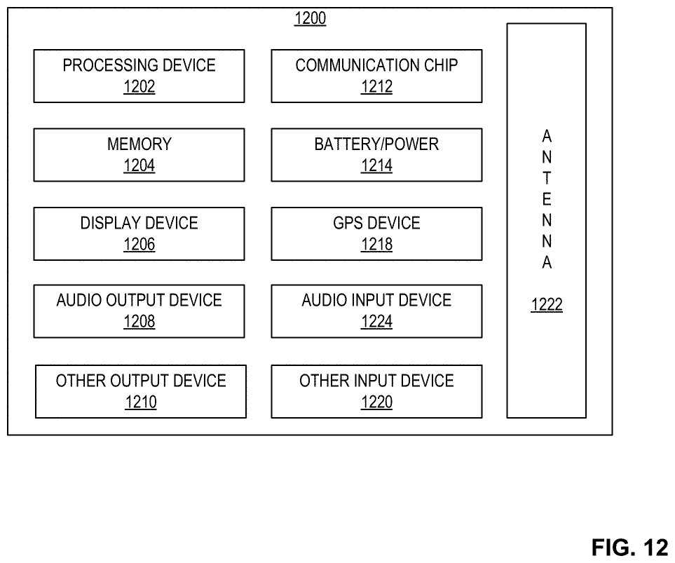

FIG. 8 is a top view of an example wafer 800 and example dies 802 that may include one or more example substrate-gated group III-V transistors (e.g., one or more of the first example substrate-gated group III-V transistor 200 of FIG. 2, and/or one or more of the second example substrate-gated group III-V transistor 500 of FIG. 5) constructed in accordance with the teachings of this disclosure, or may be included in an IC package whose substrate includes one or more substrate-gated group III-V transistors (e.g., as discussed below with reference to FIG. 10) in accordance with any of the examples disclosed herein. The wafer 800 may be composed of semiconductor material and may include one or more dies 802 having IC structures formed on a surface of the wafer 800. Each of the dies 802 may be a repeating unit of a semiconductor product that includes any suitable IC. After the fabrication of the semiconductor product is complete, the wafer 800 may undergo a singulation process in which the dies 802 are separated from one another to provide discrete “chips” of the semiconductor product. The die 802 may include one or more example substrate-gated group III-V transistors (e.g., as discussed below with reference to FIG. 9), one or more transistors (e.g., some of the transistors 940 of FIG. 9, discussed below) and/or supporting circuitry to route electrical signals to the transistors, as well as any other IC components. In some examples, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processing device (e.g., the processing device 1202 of FIG. 12) or other logic that is configured to store information in the memory devices or execute instructions stored in the memory array.

FIG. 9 is a cross-sectional side view of an IC device 900 that may include one or more example substrate-gated group III-V transistors (e.g., one or more of the first example substrate-gated group III-V transistor 200 of FIG. 2, and/or one or more of the second example substrate-gated group III-V transistor 500 of FIG. 5) constructed in accordance with the teachings of this disclosure, or may be included in an IC package whose substrate includes one or more substrate-gated group III-V transistors (e.g., as discussed below with reference to FIG. 10), in accordance with any of the examples disclosed herein. One or more of the IC devices 900 may be included in one or more dies 802 (FIG. 8). The IC device 900 may be formed on a substrate 902 (e.g., the wafer 800 of FIG. 8) and may be included in a die (e.g., the die 802 of FIG. 8). The substrate 902 may be a semiconductor substrate composed of semiconductor material systems including, for example, n-type or p-type materials systems (or a combination of both). The substrate 902 may include, for example, a crystalline substrate formed using a bulk silicon or a silicon-on-insulator (SOI) substructure. In some examples, the substrate 902 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 902. Although a few examples of materials from which the substrate 902 may be formed are described here, any material that may serve as a foundation for an IC device 900 may be used. The substrate 902 may be part of a singulated die (e.g., the dies 802 of FIG. 8) or a wafer (e.g., the wafer 800 of FIG. 8).

The IC device 900 may include one or more device layers 904 disposed on the substrate 902. The device layer 904 may include features of one or more transistors 940 (e.g., metal oxide semiconductor field-effect transistors (MOSFETs)) formed on the substrate 902. The device layer 904 may include, for example, one or more source and/or drain (S/D) regions 920, a gate 922 to control current flow in the transistors 940 between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, and conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 940 along the source-channel-drain direction, the gate electrode may consist of a U-shaped structure that includes a bottom portion substantially parallel to the surface of the substrate and two sidewall portions that are substantially perpendicular to the top surface of the substrate. In other examples, at least one of the metal layers that form the gate electrode may simply be a planar layer that is substantially parallel to the top surface of the substrate and does not include sidewall portions substantially perpendicular to the top surface of the substrate. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used. For example, two pairs, three pairs, or four pairs of sidewall spacers may be formed on opposing sides of the gate stack.

The S/D regions 920 may be formed within the substrate 902 adjacent to the gate 922 of each transistor 940. The S/D regions 920 may be formed using an implantation/diffusion process or an etching/deposition process, for example. In the former process, dopants such as boron, aluminum, antimony, phosphorous, or arsenic may be ion-implanted into the substrate 902 to form the S/D regions 920. An annealing process that activates the dopants and causes them to diffuse farther into the substrate 902 may follow the ion-implantation process. In the latter process, the substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 920 may be formed using one or more alternate semiconductor materials such as germanium or a group III-V material or alloy. In further examples, one or more layers of metal and/or metal alloys may be used to form the S/D regions 920.

In some examples, the device layer 904 may include one or more example substrate-gated group III-V transistors (e.g., one or more of the first example substrate-gated group III-V transistor 200 of FIG. 2, and/or one or more of the second example substrate-gated group III-V transistor 500 of FIG. 5), in addition to or instead of transistors 940. Any number and structure of substrate-gated group III-V transistors may be included in a device layer 904. A substrate-gated group III-V transistor included in a device layer 904 may be referred to as a “front end” device. In some examples, the IC device 900 may not include any front end substrate-gated group III-V transistors. One or more substrate-gated group III-V transistors in the device layer 904 may be coupled to any suitable other ones of the devices in the device layer 904, to any devices in the metallization stack 919 (discussed below), and/or to one or more of the conductive contacts 936 (discussed below).

Electrical signals, such as power and/or input/output (I/O) signals, may be routed to and/or from the devices (e.g., transistors 940 and/or substrate-gated group III-V transistors) of the device layer 904 through one or more interconnect layers disposed on the device layer 904 (illustrated in FIG. 9 as interconnect layers 906, 908, and 910). For example, electrically conductive features of the device layer 904 (e.g., the gate 922 and the S/D contacts 924) may be electrically coupled with the interconnect structures 928 of the interconnect layers 906, 908, 910. The one or more interconnect layers 906, 908, 910 may form a metallization stack (also referred to as an “ILD stack”) 919 of the IC device 900. In some examples, one or more substrate-gated group III-V transistors may be disposed in one or more of the interconnect layers 906, 908, 910, in accordance with any of the techniques disclosed herein. Any number and structure of substrate-gated group III-V transistors may be included in any one or more of the layers in a metallization stack 919. A substrate-gated group III-V transistor included in the metallization stack 919 may be referred to as a “back-end” device. In some examples, the IC device 900 may not include any back-end substrate-gated group III-V transistors. In some examples, the IC device 900 may include both front- and back-end substrate-gated group III-V transistors. One or more substrate-gated group III-V transistors in the metallization stack 919 may be coupled to any suitable ones of the devices in the device layer 904, and/or to one or more of the conductive contacts 936 (discussed below).

The interconnect structures 928 may be arranged within the interconnect layers 906, 908, 910 to route electrical signals according to a wide variety of designs (in particular, the arrangement is not limited to the particular configuration of interconnect structures 928 depicted in FIG. 9). Although a particular number of interconnect layers 906, 908, 910 is depicted in FIG. 9, examples of the present disclosure include IC devices having more or fewer interconnect layers than depicted.

In some examples, the interconnect structures 928 may include lines 928a and/or vias 928b filled with an electrically conductive material such as a metal. The lines 928a may be arranged to route electrical signals in a direction of a plane that is substantially parallel with a surface of the substrate 902 upon which the device layer 904 is formed. For example, the lines 928a may route electrical signals in a direction in and out of the page from the perspective of FIG. 9. The vias 928b may be arranged to route electrical signals in a direction of a plane that is substantially perpendicular to the surface of the substrate 902 upon which the device layer 904 is formed. In some examples, the vias 928b may electrically couple lines 928a of different interconnect layers 906, 908, 910 together.

The interconnect layers 906, 908, 910 may include a dielectric material 926 disposed between the interconnect structures 928, as shown in FIG. 9. In some examples, the dielectric material 926 disposed between the interconnect structures 928 in different ones of the interconnect layers 906, 908, 910 may have different compositions. In other examples, the composition of the dielectric material 926 between different interconnect layers 906, 908, 910 may be the same.

A first interconnect layer 906 (referred to as Metal 1 or “M1”) may be formed directly on the device layer 904. In some examples, the first interconnect layer 906 may include lines 928a and/or vias 928b, as shown. The lines 928a of the first interconnect layer 906 may be coupled with contacts (e.g., the S/D contacts 924) of the device layer 904.

A second interconnect layer 908 (referred to as Metal 2 or “M2”) may be formed directly on the first interconnect layer 906. In some examples, the second interconnect layer 908 may include vias 928b to couple the lines 928a of the second interconnect layer 908 with the lines 928a of the first interconnect layer 906. Although the lines 928a and the vias 928b are structurally delineated with a line within each interconnect layer (e.g., within the second interconnect layer 908) for the sake of clarity, the lines 928a and the vias 928b may be structurally and/or materially contiguous (e.g., simultaneously filled during a dual-damascene process) in some examples.

A third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some examples, the interconnect layers that are “higher up” in the metallization stack 919 in the IC device 900 (i.e., further away from the device layer 904) may be thicker.

The IC device 900 may include a solder resist material 934 (e.g., polyimide or similar material) and one or more conductive contacts 936 formed on the interconnect layers 906, 908, 910. In FIG. 9, the conductive contacts 936 are illustrated as taking the form of bond pads. The conductive contacts 936 may be electrically coupled with the interconnect structures 928 and configured to route the electrical signals of the transistor(s) 940 to other external devices. For example, solder bonds may be formed on the one or more conductive contacts 936 to mechanically and/or electrically couple a chip including the IC device 900 with another component (e.g., a circuit board). The IC device 900 may include additional or alternate structures to route the electrical signals from the interconnect layers 906, 908, 910. For example, the conductive contacts 936 may include other analogous features (e.g., posts) that route the electrical signals to external components.

FIG. 10 is a cross-sectional view of an example IC package 1050 that may include one or more example substrate-gated group III-V transistors (e.g., one or more of the first example substrate-gated group III-V transistor 200 of FIG. 2, and/or one or more of the second example substrate-gated group III-V transistor 500 of FIG. 5) constructed in accordance with the teachings of this disclosure. The package substrate 1052 may be formed of a dielectric material, and may have conductive pathways extending through the dielectric material between the face 1072 and the face 1074, or between different locations on the face 1072, and/or between different locations on the face 1074. These conductive pathways may take the form of any of the interconnects 928 discussed above with reference to FIG. 9. Any number of substrate-gated group III-V transistors (with any suitable structure) may be included in a package substrate 1052. In some examples, no substrate-gated group III-V transistors may be included in the package substrate 1052.

The IC package 1050 may include a die 1056 coupled to the package substrate 1052 via conductive contacts 1054 of the die 1056, first-level interconnects 1058, and conductive contacts 1060 of the package substrate 1052. The conductive contacts 1060 may be coupled to conductive pathways 1062 through the package substrate 1052, allowing circuitry within the die 1056 to electrically couple to various ones of the conductive contacts 1064 or to the substrate-gated group III-V transistor (or to other devices included in the package substrate 1052, not shown). The first-level interconnects 1058 illustrated in FIG. 10 are solder bumps, but any suitable first-level interconnects 1058 may be used. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket).

In some examples, an underfill material 1066 may be disposed between the die 1056 and the package substrate 1052 around the first-level interconnects 1058, and a mold compound 1068 may be disposed around the die 1056 and in contact with the package substrate 1052. In some examples, the underfill material 1066 may be the same as the mold compound 1068. Example materials that may be used for the underfill material 1066 and the mold compound 1068 are epoxy mold materials, as suitable. Second-level interconnects 1070 may be coupled to the conductive contacts 1064. The second-level interconnects 1070 illustrated in FIG. 10 are solder balls (e.g., for a ball grid array arrangement), but any suitable second-level interconnects 1070 may be used (e.g., pins in a pin grid array arrangement or lands in a land grid array arrangement). The second-level interconnects 1070 may be used to couple the IC package 1050 to another component, such as a circuit board (e.g., a motherboard), an interposer, or another IC package, as known in the art and as discussed below with reference to FIG. 11.

In FIG. 10, the IC package 1050 is a flip chip package, and includes a substrate-gated group III-V transistor in the package substrate 1052. Any number of substrate-gated group III-V transistors (with any suitable structure) may be included in a package substrate 1052. In some examples, no substrate-gated group III-V transistor may be included in the package substrate 1052. The die 1056 may take the form of any of the examples of the die 802 discussed herein (e.g., may include any of the examples of the IC device 900). In some examples, the die 1056 may include one or more substrate-gated group III-V transistors (e.g., as discussed above with reference to FIG. 8 and FIG. 9). In other examples, the die 1056 may not include any substrate-gated group III-V transistors.

Although the IC package 1050 illustrated in FIG. 10 is a flip chip package, other package architectures may be used. For example, the IC package 1050 may be a ball grid array (BGA) package, such as an embedded wafer-level ball grid array (eWLB) package. In another example, the IC package 1050 may be a wafer-level chip scale package (WLCSP) or a panel fanout (FO) package. Although a single die 1056 is illustrated in the IC package 1050 of FIG. 10, an IC package 1050 may include multiple dies 1056 (e.g., with one or more of the multiple dies 1056 coupled to substrate-gated group III-V transistors included in the package substrate 1052). An IC package 1050 may include additional passive components, such as surface-mount resistors, capacitors, and inductors disposed on the first face 1072 or the second face 1074 of the package substrate 1052. More generally, an IC package 1050 may include any other active or passive components known in the art.

FIG. 11 is a cross-sectional side view of an IC device assembly 1100 that may include one or more IC packages or other electronic components (e.g., a die) including one or more example substrate-gated group III-V transistors (e.g., one or more of the first example substrate-gated group III-V transistor 200 of FIG. 2, and/or one or more of the second example substrate-gated group III-V transistor 500 of FIG. 5) constructed in accordance with the teachings of this disclosure. The IC device assembly 1100 includes a number of components disposed on a circuit board 1102 (which may be, e.g., a motherboard). The IC device assembly 1100 includes components disposed on a first face 1140 of the circuit board 1102 and an opposing second face 1142 of the circuit board 1102. Generally, components may be disposed on one or both faces 1140 and 1142. Any of the IC packages discussed below with reference to the IC device assembly 1100 may take the form of any of the examples of the IC package 1050 discussed above with reference to FIG. 10 (e.g., may include one or more substrate-gated group III-V transistors in a package substrate 1052 or in a die).

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104. Indeed, additional interposers may be coupled to the interposer 1104. The interposer 1104 may provide an intervening substrate used to bridge the circuit board 1102 and the IC package 1120. The IC package 1120 may be or include, for example, a die (the die 802 of FIG. 8), an IC device (e.g., the IC device 900 of FIG. 9), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104. In other examples, the IC package 1120 and the circuit board 1102 may be attached to a same side of the interposer 1104. In some examples, three or more components may be interconnected by way of the interposer 1104.

The interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In some examples, the interposer 1104 may include one or more substrate-gated group III-V transistors.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include an IC package 1126 and an IC package 1132 coupled together by coupling components 1130 such that the IC package 1126 is disposed between the circuit board 1102 and the IC package 1132. The coupling components 1128 and 1130 may take the form of any of the examples of the coupling components 1116 discussed above, and the IC packages 1126 and 1132 may take the form of any of the examples of the IC package 1120 discussed above. The package-on-package structure 1134 may be configured in accordance with any of the package-on-package structures known in the art.

FIG. 12 is a block diagram of an example electrical device 1200 that may include one or more example substrate-gated group III-V transistors (e.g., one or more of the first example substrate-gated group III-V transistor 200 of FIG. 2, and/or one or more of the second example substrate-gated group III-V transistor 500 of FIG. 5) constructed in accordance with the teachings of this disclosure. For example, any suitable ones of the components of the electrical device 1200 may include one or more of the IC packages 1050, IC devices 900, or dies 802 disclosed herein. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include a processing device 1202 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the processing device 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1224 (or corresponding interface circuitry, as discussed above). The audio input device 1224 may include any device that generates a signal representative of a sound, such as microphones, microphone arrays, or digital instruments (e.g., instruments having a musical instrument digital interface (MIDI) output).

The electrical device 1200 may include a GPS device 1218 (or corresponding interface circuitry, as discussed above). The GPS device 1218 may be in communication with a satellite-based system and may receive a location of the electrical device 1200, as known in the art.

The electrical device 1200 may include an other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

From the foregoing, it will be appreciated that the disclosed substrate-gated group III-V transistors and associated fabrication methods advantageously include and/or provide for one or more gate(s) located against and/or on (e.g., formed within a cavity of) a substrate of the substrate-gated group III-V transistor. The substrate-based location of the gate(s) advantageously enables the fabrication of additional structures on the topside of the substrate-gated group III-V transistor, thereby enabling the disclosed substrate-gated group III-V transistors to be implemented as backplane transistors for μLED applications (e.g., group III-V μLEDs).

Examples may include subject matter such as the substrate-gated group III-V transistors or the methods for fabricating substrate-gated group III-V transistors described herein. Example 1 is a transistor. The transistor of Example 1 comprises a substrate, a gate, and a layer. The gate is located on the substrate. The layer includes a group III material and a group V material. The layer is located on the substrate and the gate. The gate is positioned between the substrate and the layer.

Example 2 includes the subject matter of Example 1, wherein the layer is a first layer. The transistor of Example 2 further includes a polarization layer located on the first layer. The polarization layer is to generate a two-dimensional electron gas (2DEG) within the first layer.

Example 3 includes the subject matter of Example 2. The transistor of Example 3 further includes an n-type doped source and an n-type doped drain respectively located on the first layer. The n-type doped source and the n-type doped drain are to contact the 2DEG.

Example 4 includes the subject matter of Example 3. The transistor of Example 4 further includes a first regrowth layer located on the polarization layer, the n-type doped source, and the n-type doped drain.

Example 5 includes the subject matter of Example 4. The transistor of Example 5 further includes a light-emitting diode (LED) structure located on the polarization layer.

Example 6 includes the subject matter of Example 5, wherein the LED structure includes a base, a quantum well, and a p-type doped cap. The base includes a group III material and a group V material. The base is located on the polarization layer. The quantum well is located on the base. The p-type doped cap includes a group III material and a group V material. The p-type doped cap is located on the quantum well.

Example 7 includes the subject matter of either of Examples 5 or 6. The transistor of Example 7 further includes a second regrowth layer located on the n-type doped source, the n-type doped drain, the first regrowth layer, and the LED structure.

Example 8 includes the subject matter of Example 7. The transistor of Example 8 further includes a source contact located on the n-type doped source, a drain contact located on the n-type doped drain, and an LED anode contact located on the LED structure.

Example 9 includes the subject matter of Example 8. The transistor of Example 9 further includes an interlayer dielectric (ILD) layer located on the LED structure, the second regrowth layer, the source contact, the drain contact, and the LED anode contact.

Example 10 includes the subject matter of Example 8, wherein the gate is a first gate, the n-type doped source is a first n-type doped source, the n-type doped drain is a first n-type doped drain, the LED structure is a first LED structure, the source contact is a first source contact, the drain contact is a first drain contact, and the LED anode contact is a first LED anode contact. The transistor of Example 10 further includes a second gate located on the substrate. The second gate is positioned between the substrate and the first layer. The transistor of Example 10 further includes a second n-type doped source and a second n-type doped drain respectively located on the first layer. The second n-type doped source and the second n-type doped drain are to contact the 2DEG. The transistor of Example 10 further includes a second LED structure located on the polarization layer, a second source contact located on the second n-type doped source, a second drain contact located on the second n-type doped drain, and a second LED anode contact located on the second LED structure.

Example 11 includes the subject matter of Example 10. The transistor of Example 11 further includes an isolation structure located on the first layer. The isolation structure is to block the 2DEG between the first n-type doped drain and the second n-type doped source.

Example 12 includes the subject matter of either of Examples 10 or 11, wherein the first LED structure is to produce light of a first color, and the second LED structure is to produce light of a second color different from the first color.

Example 13 is a transistor. The transistor of Example 13 comprises a substrate, means for receiving a voltage to generate an electric field, and a layer. The means for receiving a voltage to generate an electric field is located on the substrate. The layer includes a group III material and a group V material. The layer is located on the substrate and the means for receiving a voltage to generate an electric field. The means for receiving a voltage to generate an electric field is positioned between the substrate and the layer.

Example 14 includes the subject matter of Example 13. The transistor of Example 14 further includes means for generating a two-dimensional electron gas (2DEG) within the layer. The means for generating a 2DEG is located on the layer.

Example 15 includes the subject matter of Example 14. The transistor of Example 15 further includes an n-type doped source and an n-type doped drain respectively located on the layer. The n-type doped source and the n-type doped drain are to contact the 2DEG.

Example 16 includes the subject matter of Example 15, wherein the layer is a first layer. The transistor of Example 16 further includes a first regrowth layer located on the means for generating a 2DEG, the n-type doped source, and the n-type doped drain.

Example 17 includes the subject matter of Example 16. The transistor of Example 17 further includes a light-emitting diode (LED) structure located on the means for generating a 2DEG.

Example 18 includes the subject matter of Example 17, wherein the LED structure includes a base, a quantum well, and a p-type doped cap. The base includes a group III material and a group V material. The base is located on the means for generating a 2DEG. The quantum well is located on the base. The p-type doped cap includes a group III material and a group V material. The p-type doped cap is located on the quantum well.

Example 19 includes the subject matter of either of Examples 17 or 18. The transistor of Example 19 further includes a second regrowth layer located on the n-type doped source, the n-type doped drain, the first regrowth layer, and the LED structure.

Example 20 includes the subject matter of Example 19. The transistor of Example 20 further includes a source contact located on the n-type doped source, a drain contact located on the n-type doped drain, and an LED anode contact located on the LED structure.

Example 21 includes the subject matter of Example 20. The transistor of Example 21 further includes an interlayer dielectric (ILD) layer located on the LED structure, the second regrowth layer, the source contact, the drain contact, and the LED anode contact.

Example 22 includes the subject matter of Example 20, wherein the means for receiving a voltage to generate an electric field is a first means for receiving a voltage to generate a first electric field, the n-type doped source is a first n-type doped source, the n-type doped drain is a first n-type doped drain, the LED structure is a first LED structure, the source contact is a first source contact, the drain contact is a first drain contact, and the LED anode contact is a first LED anode contact. The transistor of Example 22 further includes a second means for receiving a voltage to generate a second electric field. The second means for receiving a voltage is located on the substrate and positioned between the substrate and the first layer. The transistor of Example 22 further includes a second n-type doped source and a second n-type doped drain respectively located on the first layer. The second n-type doped source and the second n-type doped drain are to contact the 2DEG. The transistor of Example 22 further includes a second LED structure located on the means for generating a 2DEG, a second source contact located on the second n-type doped source, a second drain contact located on the second n-type doped drain, and a second LED anode contact located on the second LED structure.

Example 23 includes the subject matter of Example 22. The transistor of Example 23 further includes an isolation structure located on the first layer. The isolation structure is to block the 2DEG between the first n-type doped drain and the second n-type doped source.

Example 24 includes the subject matter of either of Examples 22 or 23, wherein the first LED structure is to produce light of a first color, and the second LED structure is to produce light of a second color different from the first color.

Example 25 is a system. The system of Example 25 comprises a processing device. The processing device of Example 25 includes a communication chip and a transistor. The transistor of Example 25 includes a substrate, a gate, and a layer. The gate is located on the substrate. The layer includes a group III material and a group V material. The layer is located on the substrate and the gate. The gate is positioned between the substrate and the layer.

Example 26 includes the subject matter of Example 25, wherein the layer is a first layer. The transistor of Example 26 further includes a polarization layer located on the first layer. The polarization layer is to generate a two-dimensional electron gas (2DEG) within the first layer.

Example 27 includes the subject matter of Example 26. The transistor of Example 27 further includes an n-type doped source and an n-type doped drain respectively located on the first layer. The n-type doped source and the n-type doped drain are to contact the 2DEG.

Example 28 includes the subject matter of Example 27. The transistor of Example 28 further includes a first regrowth layer located on the polarization layer, the n-type doped source, and the n-type doped drain.

Example 29 includes the subject matter of Example 28. The transistor of Example 29 further includes a light-emitting diode (LED) structure located on the polarization layer.

Example 30 includes the subject matter of Example 29, wherein the LED structure includes a base, a quantum well, and a p-type doped cap. The base includes a group III material and a group V material. The base is located on the polarization layer. The quantum well is located on the base. The p-type doped cap includes a group III material and a group V material. The p-type doped cap is located on the quantum well.

Example 31 includes the subject matter of either of Examples 29 or 30. The transistor of Example 31 further includes a second regrowth layer located on the n-type doped source, the n-type doped drain, the first regrowth layer, and the LED structure.

Example 32 includes the subject matter of Example 31. The transistor of Example 32 further includes a source contact located on the n-type doped source, a drain contact located on the n-type doped drain, and an LED anode contact located on the LED structure.

Example 33 includes the subject matter of Example 32. The transistor of Example 33 further includes an interlayer dielectric (ILD) layer located on the LED structure, the second regrowth layer, the source contact, the drain contact, and the LED anode contact.

Example 34 includes the subject matter of Example 32, wherein the gate is a first gate, the n-type doped source is a first n-type doped source, the n-type doped drain is a first n-type doped drain, the LED structure is a first LED structure, the source contact is a first source contact, the drain contact is a first drain contact, and the LED anode contact is a first LED anode contact. The transistor of Example 34 further includes a second gate located on the substrate. The second gate is positioned between the substrate and the first layer. The transistor of Example 34 further includes a second n-type doped source and a second n-type doped drain respectively located on the first layer. The second n-type doped source and the second n-type doped drain are to contact the 2DEG. The transistor of Example 34 further includes a second LED structure located on the polarization layer, a second source contact located on the second n-type doped source, a second drain contact located on the second n-type doped drain, and a second LED anode contact located on the second LED structure.

Example 35 includes the subject matter of Example 34. The transistor of Example 35 further includes an isolation structure located on the first layer. The isolation structure is to block the 2DEG between the first n-type doped drain and the second n-type doped source.

Example 36 includes the subject matter of either of Examples 34 or 35, wherein the first LED structure is to produce light of a first color, and the second LED structure is to produce light of a second color different from the first color.

Example 37 is a method of fabricating a transistor. The method of Example 37 comprises locating a gate on a substrate, and locating a layer on the substrate and the gate. The layer includes a group III material and a group V material. The gate is positioned between the substrate and the layer.

Example 38 includes the subject matter of Example 37, wherein the layer is a first layer. The method of Example 38 further includes locating a polarization layer on the first layer. The polarization layer is to generate a two-dimensional electron gas (2DEG) within the first layer.

Example 39 includes the subject matter of Example 38. The method of Example 39 further includes locating an n-type doped source and an n-type doped drain on the first layer. The n-type doped source and the n-type doped drain are to contact the 2DEG.

Example 40 includes the subject matter of Example 39. The method of Example 40 further includes locating a first regrowth layer on the polarization layer, the n-type doped source, and the n-type doped drain.

Example 41 includes the subject matter of Example 40. The method of Example 41 further includes locating a light-emitting diode (LED) structure on the polarization layer.

Example 42 includes the subject matter of Example 41. The method of Example 42 further includes locating a second regrowth layer on the n-type doped source, the n-type doped drain, the first regrowth layer, and the LED structure.

Example 43 includes the subject matter of Example 42. The method of Example 43 further includes locating a source contact on the n-type doped source, locating a drain contact on the n-type doped drain, and locating an LED anode contact on the LED structure.

Example 44 includes the subject matter of Example 43. The method of Example 44 further includes locating an interlayer dielectric (ILD) layer on the LED structure, the second regrowth layer, the source contact, the drain contact, and the LED anode contact.

Example 45 includes the subject matter of Example 43, wherein the gate is a first gate, the n-type doped source is a first n-type doped source, the n-type doped drain is a first n-type doped drain, the LED structure is a first LED structure, the source contact is a first source contact, the drain contact is a first drain contact, and the LED anode contact is a first LED anode contact. The method of Example 45 further includes locating a second gate on the substrate. The second gate is positioned between the substrate and the first layer. The method of Example 45 further includes locating a second n-type doped source and a second n-type doped drain on the first layer. The second n-type doped source and the second n-type doped drain are to contact the 2DEG. The method of Example 45 further includes locating a second LED structure on the polarization layer, locating a second source contact on the second n-type doped source, locating a second drain contact on the second n-type doped drain, and locating a second LED anode contact on the second LED structure.

Example 46 includes the subject matter of Example 45. The method of Example 46 further includes locating an isolation structure on the first layer. The isolation structure is to block the 2DEG between the first n-type doped drain and the second n-type doped source.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

1-25. (canceled)

26. A transistor, comprising:
a substrate;
a gate on the substrate; and
a layer comprising a group III material and a group V material, the layer on the substrate and the gate, the gate positioned between the substrate and the layer.

27. The transistor of claim 26, wherein the layer is a first layer, the transistor further comprising a polarization layer on the first layer, the polarization layer to generate a two-dimensional electron gas (2DEG) within the first layer.

28. The transistor of claim 27, further comprising an n-type doped source and an n-type doped drain on the first layer, the n-type doped source and the n-type doped drain to contact the 2DEG.

29. The transistor of claim 28, further comprising a first regrowth layer on the polarization layer, the n-type doped source, and the n-type doped drain.

30. The transistor of claim 29, further comprising a light-emitting diode (LED) structure on the polarization layer.

31. The transistor of claim 30, wherein the LED structure comprises:
a base comprising a group III material and a group V material, the base on the polarization layer;
a quantum well on the base; and
a p-type doped cap comprising a group III material and a group V material, the p-type doped cap on the quantum well.

32. The transistor of claim 30, further comprising a second regrowth layer on the n-type doped source, the n-type doped drain, the first regrowth layer, and the LED structure.

33. The transistor of claim 32, further comprising:
a source contact on the n-type doped source;
a drain contact on the n-type doped drain; and
an LED anode contact on the LED structure.

34. The transistor of claim 33, wherein the gate is a first gate, the n-type doped source is a first n-type doped source, the n-type doped drain is a first n-type doped drain, the LED structure is a first LED structure, the source contact is a first source contact, the drain contact is a first drain contact, and the LED anode contact is a first LED anode contact, the transistor further comprising:
a second gate on the substrate, the second gate between the substrate and the first layer;
a second n-type doped source and a second n-type doped drain on the first layer, the second n-type doped source and the second n-type doped drain to contact the 2DEG;
a second LED structure on the polarization layer;
a second source contact on the second n-type doped source;
a second drain contact on the second n-type doped drain; and
a second LED anode contact on the second LED structure.

35. The transistor of claim 34, further comprising an isolation structure on the first layer, the isolation structure to block the 2DEG between the first n-type doped drain and the second n-type doped source.

36. A transistor, comprising:
a substrate;
means for receiving a voltage to generate an electric field, the means for receiving a voltage being on the substrate; and
a layer comprising a group III material and a group V material, the layer on the substrate and the means for receiving a voltage, the means for receiving a voltage positioned between the substrate and the layer.

37. The transistor of claim 36, the transistor further comprising means for generating a two-dimensional electron gas (2DEG) within the layer, the means for generating a 2DEG on the layer.

38. The transistor of claim 37, further comprising an n-type doped source and an n-type doped drain on the layer, the n-type doped source and the n-type doped drain to contact the 2DEG.

39. The transistor of claim 38, wherein the layer is a first layer, the transistor further comprising a first regrowth layer on the means for generating a 2DEG, the n-type doped source, and the n-type doped drain.

40. The transistor of claim 39, further comprising a light-emitting diode (LED) structure on the means for generating a 2DEG.

41. A system, comprising:
a communication chip; and
a transistor comprising:
a substrate;
a gate on the substrate; and
a layer comprising a group III material and a group V material, the layer on the substrate and the gate, the gate positioned between the substrate and the layer.

42. The system of claim 41, wherein the layer is a first layer, the transistor further comprising a polarization layer on the first layer, the polarization layer to generate a two-dimensional electron gas (2DEG) within the first layer.

43. The system of claim 42, the transistor further comprising an n-type doped source and an n-type doped drain on the first layer, the n-type doped source and the n-type doped drain to contact the 2DEG.

44. The system of claim 43, the transistor further comprising a first regrowth layer on the polarization layer, the n-type doped source, and the n-type doped drain.

45. The system of claim 44, the transistor further comprising a light-emitting diode (LED) structure on the polarization layer.
